(19) United States
(12) Patent Application Publication
(10) Pub. No.: US 2023/0207017 A1
(43) Pub. Date: Jun. 29, 2023

(54) STORAGE DEVICE AND METHOD OF OPERATING STORAGE DEVICE

(71) Applicant: SAMSUNG ELECTRONICS CO., LTD, Suwon-si (KR)

(72) Inventors: Eun Chu OH, Hwaseong-si (KR); Junyeong SEOK, Seoul (KR); Younggul SONG, Suwon-si (KR)

(21) Appl. No.: 17/810,894

(22) Filed: Jul. 6, 2022

(30) Foreign Application Priority Data
Dec. 23, 2021 (KR) 10-2021-0186141

(51) Int. Cl. G11C 16/10; G11C 16/28; G11C 16/34; G11C 16/08; G11C 16/32

(52) U.S. Cl. CPC G11C 16/102; G11C 16/28; G11C 16/3495; G11C 16/08; G11C 16/32

(57) ABSTRACT

A storage device includes a nonvolatile memory device and a storage controller to control operation of the nonvolatile memory device. The storage controller assigns a program operation associated with data to be programmed, to one of a first program operation or a second program operation, controls the nonvolatile memory device to perform the first program operation on first memory blocks and to perform the second program operation on at least one second memory block, and controls the nonvolatile memory to select one of the first program operation on a third memory block in an erase state or the second program operation on the second memory block, and to perform the selected program operation after the first program operation on the first memory blocks is completed.

### CROSS-REFERENCE

This U.S. patent application claims the benefit of priority under 35 USC § 119 to Korean Patent Application No. 10-2021-0186141, filed on Dec. 23, 2021 in the Korean Intellectual Property Office, the disclosure of which is incorporated by reference in its entirety herein.

### FIELD

The present disclosure generally relates to semiconductor integrated circuits, and more particularly relates to storage devices and methods of operating storage devices.

### DISCUSSION

Semiconductor memory devices may be classified into volatile memory and nonvolatile memory. Data stored in volatile memory may be lost after power-off. Data stored in nonvolatile memory are retained even after power-off. A flash memory device represents a type of nonvolatile memory device. A flash memory device offers a mass storage capability, relatively high noise immunity, and relatively low power operation. Therefore, flash memory devices are employed in various fields. For example, a mobile system such as a smart-phone, or a tablet personal computer (PC), may employ flash memory as a storage medium.

As fabrication processes for flash memory devices are scaled-down and memory cells of the flash memory device are stacked, the memory cells may be degraded and data retention characteristic of the memory cells may be degraded.

### SUMMARY

An embodiment of the present disclosure may provide a storage device capable of enhancing program performance without increasing a size of a buffer memory.

An embodiment of the present disclosure may provide a method of operating a storage device, capable of enhancing program performance without increasing a size of a buffer memory.

According to an embodiment, a storage device includes a nonvolatile memory device and a storage controller to control operation of the nonvolatile memory device. The nonvolatile memory device includes a memory cell array and the memory cell array includes a plurality of word-lines stacked on a substrate, a plurality of memory cells provided in a plurality of channel holes extending in a vertical direction with respect to the substrate and a word-line cut region extending in a first horizontal direction and dividing the plurality of word-lines into a plurality of memory blocks. The storage controller assigns a program operation associated with a data to be programmed, to one of a first program operation and a second program operation, assigns at least one first page of data to the first program operation based on the data and assign at least one second page of data to the second program operation based on the data. The storage controller controls the nonvolatile memory device to perform the first program operation on first memory blocks from among the plurality of memory blocks such that memory cells of the first memory blocks store the at least one first page of data and to perform the second program operation on at least one second memory block selected from the first memory blocks such that memory cells of the second memory block further store the at least one second page of data and controls the nonvolatile memory device to select one of the first program operation on a third memory block in erase state and the second program operation on the second memory block and to perform the selected program operation after the first program operation on the first memory blocks is completed.

According to an embodiment, a storage device includes a nonvolatile memory device and a storage controller to control operation of the nonvolatile memory device. The nonvolatile memory device includes a memory cell array and the memory cell array includes a plurality of word-lines stacked on a substrate, a plurality of memory cells provided in a plurality of channel holes extending in a vertical direction with respect to the substrate and a word-line cut region extending in a first horizontal direction and dividing the plurality of word-lines into a plurality of memory blocks. The storage controller assigns a program operation to be performed on a data to be programmed, to one of a first program operation and a second program operation, assigns at least one first page of data to the first program operation based on the data and assigns at least one second page of data to the second program operation based on the program data. The storage controller assigns the plurality of memory blocks to first memory blocks on which the first program operation to be performed and at least one second memory block on which the second program operation to be performed, assigns a first logical address of each of the first memory blocks to a first physical address, assigns a second logical address of the at least one second memory block to a second physical address, control the nonvolatile memory device to perform the first program operation on first memory blocks from among the plurality of memory blocks such that memory cells of the first memory blocks store the at least one first page of data and to perform the second program operation on at least one second memory block selected from the first memory blocks such that memory cells of the second memory block further store the at least one second page of data and controls the nonvolatile memory device to select one of the first program operation on a third memory block in erase state and the second program operation on the second memory block and to perform the selected program operation after the first program operation on the first memory blocks is completed.

According to an embodiment, there is provided a method of operating a storage device including a nonvolatile memory device and a storage controller to control the nonvolatile memory device. The memory cell array includes a plurality of word-lines stacked on a substrate, a plurality of memory cells provided in a plurality of channel holes extending in a vertical direction with respect to the substrate and a word-line cut region extending in a first horizontal direction and dividing the plurality of word-lines into a plurality of memory blocks. According to the method, a first program command, a physical address and at least one first page of data from the storage controller are received by the nonvolatile memory device, a first program operation is performed on first memory blocks from among the memory blocks such that memory cells of the first memory blocks store the at least one first page of data, a second program command, the physical address and at least one second page of data from the storage controller are received by the nonvolatile memory device and a second program operation is performed on at least one second memory block selected from the first memory blocks such that memory cells of the at least one second memory block store the at least one second page of data. One of the first program operation on a third memory block in erase state and the second program operation on the at least one second memory block is performed after the first program operation on the first memory blocks is completed.

Accordingly, when the first program operation is completed, the memory cells of the first memory blocks have the erase state and first through 2^{M}−1_th target program states instead of intermediate program states, and thus, data may be read from the memory cells of the first memory blocks. In addition, the storage controller may enhance and/or recover charge loss and/or moved threshold voltage distribution by performing the second program operation on the at least one second memory block for which the probability of degradation of memory cells is greatest from among the first memory blocks.

### BRIEF DESCRIPTION OF THE DRAWINGS

Illustrative, non-limiting embodiments will be more clearly understood from the following detailed description when taken in conjunction with the accompanying drawings, in which:

FIG. 1 is a block diagram illustrating a storage system according to an embodiment;

FIG. 2 is a block diagram illustrating the host of FIG. 1 according to an embodiment;

FIG. 3 is a block diagram illustrating an example of the storage controller in the storage device of FIG. 1 according to an embodiment;

FIG. 4 is a block diagram illustrating an example of the program/address assigner in the storage controller of FIG. 3 according to an embodiment;

FIG. 5 is a tabular diagram that illustrates an example of a degradation information table included in the on-chip memory in the storage controller of FIG. 3;

FIG. 6 is a block diagram illustrating a connection relationship between the storage controller and one nonvolatile memory device in the storage device of FIG. 1;

FIG. 7 is a block diagram illustrating the nonvolatile memory device of FIG. 6 according to an embodiment;

FIG. 8 is a projection diagram illustrating the memory cell array in the nonvolatile memory device of FIG. 7;

FIG. 9 is a circuit diagram illustrating one of the memory blocks of FIG. 8;

FIG. 10 is a hybrid diagram that illustrates an example of a structure of a NAND string in the memory block of FIG. 9;

FIG. 11 is a circuit diagram illustrating one of the memory blocks of FIG. 8;

FIG. 12 is a projection diagram illustrating one of the memory blocks of FIG. 8;

FIG. 13A is a timing diagram for describing a program operation of the storage device according to an embodiment;

FIG. 13B is a timing diagram for describing a program operation of the storage device according to an embodiment;

FIG. 14A is a graphical diagram showing a threshold voltage distribution of memory cells when a memory cell included in the memory cell array of FIG. 7 is a 3-bit TLC;

FIG. 14B is a graphical diagram showing a threshold voltage distribution of memory cells when a memory cell included in the memory cell array of FIG. 7 is a 4-bit QLC;

FIG. 15 is a hybrid diagram that illustrates a portion of a plurality of memory blocks of FIG. 8 according to an embodiment;

FIG. 16 is a hybrid diagram that illustrates that a second program operation is performed on a portion of the memory blocks of FIG. 15 according to an embodiment;

FIG. 17 is a hybrid diagram that illustrates that a first program operation is performed on a portion of the memory blocks of FIG. 15 according to an embodiment;

FIG. 18 is a hybrid diagram that illustrates a portion of a plurality of memory blocks of FIG. 8 according to an embodiment;

FIG. 19 is a hybrid diagram that illustrates that a second program operation is performed on a portion of the memory blocks of FIG. 18 according to an embodiment;

FIG. 20 is a hybrid diagram that illustrates a portion of a plurality of memory blocks of FIG. 8 according to an embodiment;

FIG. 21 is a hybrid diagram that illustrates that a second program operation is performed on a portion of the memory blocks of FIG. 20 according to an embodiment;

FIG. 22 is a graphical diagram showing enlarged first and second program states of FIG. 14A;

FIG. 23 is a schematic diagram that illustrates a cell region in which the memory cell array of FIG. 7 is formed according to an embodiment;

FIG. 24A is a cross-sectional diagram that illustrates cross-sections of strings of the memory block BLKa of FIG. 23;

FIG. 24B is a cross-sectional diagram that illustrates cross-sections of strings of the memory block BLKb of FIG. 23;

FIG. 25 is a schematic diagram that illustrates an example of a vertical structure of one of channel holes of FIG. 23;

FIG. 26 is a flowchart diagram illustrating a method of operating a storage device according to an embodiment;

FIG. 27 is a flowchart diagram illustrating a method of operating a storage device according to an embodiment;

FIG. 28 is a cross-sectional diagram of a nonvolatile memory device according to an embodiment; and

FIG. 29 is a block diagram illustrating an electronic system including a semiconductor device according to an embodiment.

### DETAILED DESCRIPTION

Embodiments of the present disclosure will be described more fully hereinafter by way of example with reference to the accompanying drawings, in which illustrative non-limiting embodiments are shown.

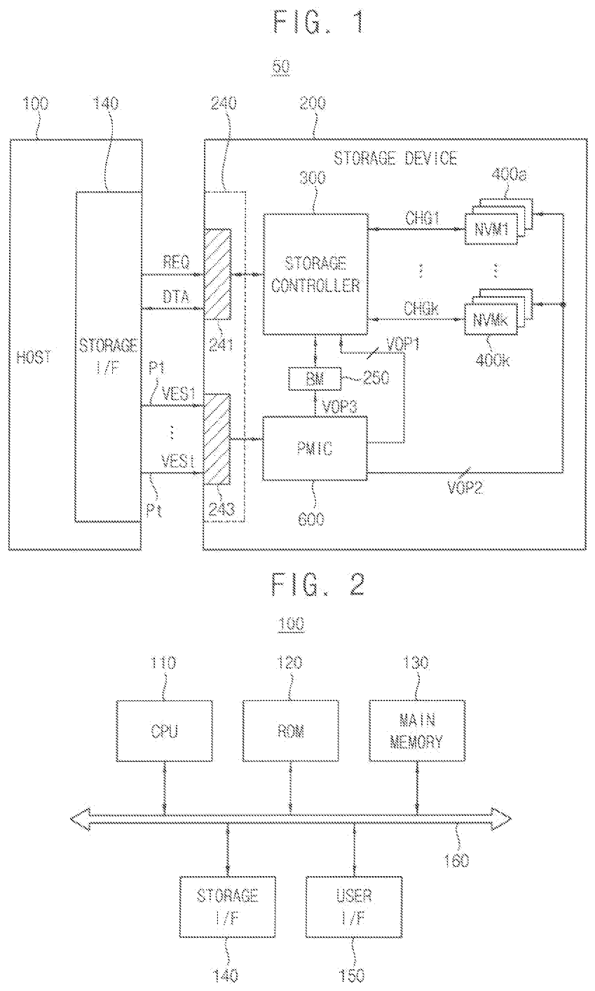

FIG. 1 illustrates a storage system according to an embodiment.

Referring to FIG. 1, a storage system 50 may include a host 100 and a storage device 200. The host 100 may include a storage interface (I/F) 140.

The storage device 200 may be any kind of storage device.

The storage device 200 may include a storage controller 300, a plurality of nonvolatile memory devices 400a to 400k (where k is an integer greater than two), a power management integrated circuit (PMIC) 600 and a host interface 240. The host interface 240 may include a signal connector 241 and a power connector 243. The storage device 200 may further include a buffer memory BM 250.

The plurality of nonvolatile memory devices 400a to 400k may be used as a storage medium of the storage device 200. In an embodiment, each of the plurality of nonvolatile memory devices 400a to 400k may include a flash memory or a vertical NAND memory device. The storage controller 300 may be coupled to the plurality of nonvolatile memory devices 400a to 400k through a plurality of channels CHG1 to CHGk, respectively.

The storage controller 300 may be configured to receive a request REQ from the host 100 and communicate data DTA with the host 100 through the signal connector 241. The storage controller 300 may write the data DTA to the plurality of nonvolatile memory devices 400a to 400k or read the data DTA from the plurality of nonvolatile memory devices 400a to 400k based on the request REQ.

The storage controller 300 may communicate the data DTA with the host 100 using the buffer memory 250 as an input/output buffer. In an embodiment, the buffer memory 250 may include a dynamic random-access memory (DRAM).

The PMIC 600 may be configured to receive a plurality of power supply voltages (e.g., external supply voltages) VES1 to VESt from the host 100 through the power connector 243. For example, the power connector 243 may include a plurality of power lines P1 to Pt, and an adaptive power supply circuit may be configured to receive the plurality of power supply voltages VES1 to VESt from the host 100 through the plurality of power lines P1 to Pt, respectively. Here, t represents a positive integer greater than one.

The PMIC 600 may generate at least one first operating voltage VOP1 used by the storage controller 300, at least one second operating voltage VOP2 used by the plurality of nonvolatile memory devices 400a to 400k, and at least one third operating voltage VOP3 used by the buffer memory 250 based on the plurality of power supply voltages VES1 to VESt.

For example, when the PMIC 600 receives all of the plurality of power supply voltages VES1 to VESt from the host 100, the PMIC 600 may generate the at least one first operating voltage VOP1, the at least one second operating voltage VOP2, and the at least one third operating voltage VOP3 using all of the plurality of power supply voltages VES1 to VESt. On the other hand, when the PMIC 600 receives less than all of the plurality of power supply voltages VES1 to VESt from the host 100, the PMIC 600 may generate the at least one first operating voltage VOP1, the at least one second operating voltage VOP2, and the at least one third operating voltage VOP3 using the received less than all of the plurality of power supply voltages VES1 to VESt received from the host 100.

FIG. 2 illustrates the host of FIG. 1 according to an embodiment.

Referring to FIG. 2, the host 100 may include a central processing unit (CPU) 110, a read-only memory (ROM) 120, a main memory 130, a storage interface (I/F) 140, a user interface (I/F) 150 and a bus 160.

The bus 160 may refer to a transmission channel via which data is transmitted between the CPU 110, the ROM 120, the main memory 130, the storage interface 140 and the user interface 150 of the host 100. The ROM 120 may store various application programs. For example, application programs supporting storage protocols such as Advanced Technology Attachment (ATA), Small Computer System Interface (SCSI), embedded Multi Media Card (eMMC), and/or Universal flash storage (UFS) protocols may be stored.

The main memory 130 may temporarily store data or programs. The user interface 150 may be a physical or virtual medium for exchanging information between a user and the host 100, a computer program, or the like, and includes physical hardware and logical software. For example, the user interface 150 may include an input device for allowing the user to manipulate the host 100, and an output device for outputting a result of processing an input from the user.

The CPU 110 may control overall operations of the host 100. The CPU 110 may generate a command and the power supply voltages VES1 to VESt for storing data in the storage device 200, or a request and/or a command and the power supply voltages VES1 to VESt for reading data from the storage device 200 by using an application stored in the ROM 120, and transmit the request and the power supply voltages VES1 to VESt to the storage device 200 via the storage interface 140.

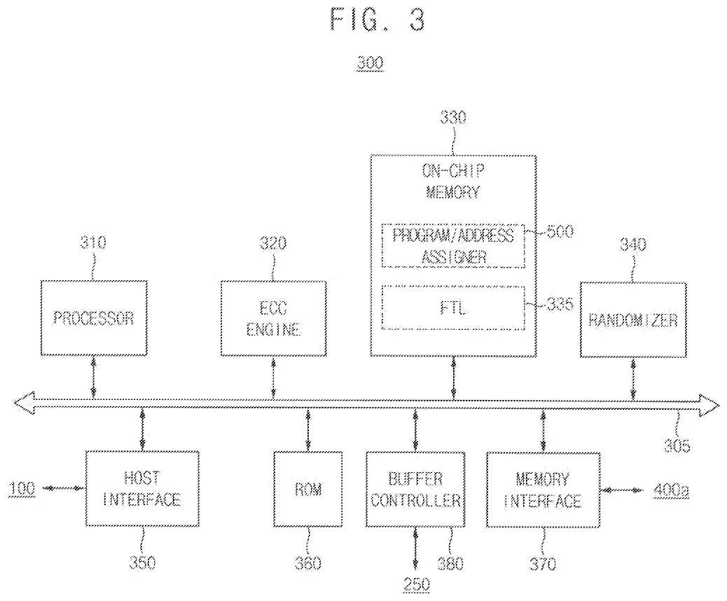

FIG. 3 illustrates an example of the storage controller in the storage device of FIG. 1 according to an embodiment.

Referring to FIG. 3, the storage controller 300 may include a processor 310, an error correction code (ECC) engine 320, an on-chip memory 330, randomizer 340, a host interface 350, a ROM 360, a buffer controller 380, and a memory interface 370 which are connected via a bus 305.

The processor 310 controls an overall operation of the storage controller 300. The processor 310 may control the ECC engine 320, the on-chip memory 330, the randomizer 340, the host interface 350, the ROM 360, the buffer controller 380 and the memory interface 370.

The processor 310 may include one or more cores (e.g., a homogeneous multi-core or a heterogeneous multi-core). The processor 310 may be or include, for example, at least one of a central processing unit (CPU), an image signal processing unit (ISP), a digital signal processing unit (DSP), a graphics processing unit (GPU), a vision processing unit (VPU), and/or a neural processing unit (NPU). The processor 310 may execute various application programs such as a flash translation layer (FTL) 335 and/or firmware, loaded onto the on-chip memory 330.

The on-chip memory 330 may store various application programs that are executable by the processor 310. The on-chip memory 330 may operate as a cache memory adjacent to the processor 310. The on-chip memory 330 may store a command, an address, and data to be processed by the processor 310 or may store a processing result of the processor 310. The on-chip memory 330 may be, for example, a storage medium or a working memory including a latch, a register, a static random-access memory (SRAM), a dynamic random-access memory (DRAM), a thyristor random-access memory (TRAM), a tightly coupled memory (TCM), or the like

The processor 310 may execute the FTL 335 loaded onto the on-chip memory 330. The FTL 335 may be loaded onto the on-chip memory 330 as firmware or a program stored in the one of the nonvolatile memory devices 400a to 400k. The FTL 335 may manage mapping between a logical address provided from the host 100 and a physical address of the nonvolatile memory devices 400a to 400k and may include an address mapping table manager configured for managing and updating an address mapping table. The FTL 335 may further perform a garbage collection operation, a wear-leveling operation, and/or the like, as well as the address mapping described above. The FTL 335 may be executed by the processor 310 for addressing one or more of the following aspects of the nonvolatile memory devices 400a to 400k: overwrite-impossible or in-place write-impossible, a life-time of a memory cell, a limited number of program-erase (PE) cycles, and/or an erase speed slower than a write speed.

The processor 310 may execute a program/address assigner 500 loaded onto the on-chip memory 330.

The program/address assigner 500 may assign a program operation to be performed on a data to be programmed in a plurality of memory blocks of plurality of nonvolatile memory devices 400a to 400k, to one of a first program operation and a second program operation, may assign M page data to the first program operation based on the data and may assign N page data to the second program operation based on the program data. Here, M may a natural number greater than zero and N may be a natural number greater than zero.

When the program/address assigner 500 assigns program operation to the first program operation, the program/address assigner 500 may assign a portion of the memory blocks to first target memory blocks on which the first program operation is to be performed based on wear-leveling information of each of the plurality of memory blocks. When the program/address assigner 500 assigns program operation to the second program operation, the program/address assigner 500 may assign at least one of the first target memory blocks to a second memory block on which the second program operation is to be performed based on degradation information of each of the first target memory blocks.

The program/address assigner 500 may assign a first logical address of each of the first target memory blocks to a first physical address, and may assign a second logical address of the at least one second target memory block to a second physical address.

The program/address assigner 500 may assign program operation to be performed on the data to one of the first program operation and the second program operation based on expected retention time information of the data and user request information on the data.

For example, the expected retention time information may correspond to an expected storing time associated with the data and the user request information may include at least one of a performance of the storage device, a latency associated with the program operation and/or a reliability of the data.

Memory cells of the nonvolatile memory devices 400a to 400k may have a physical characteristic in which a threshold voltage distribution varies due to causes, such as a program elapsed time, a temperature, program disturbance, read disturbance and or the like. For example, data stored at the nonvolatile memory devices 400a to 400k may become erroneous due to the above causes.

The storage controller 300 may utilize a variety of error correction techniques to correct such errors. For example, the storage controller 300 may include the ECC engine 320. The ECC engine 320 may correct errors which occur in the data stored in the nonvolatile memory devices 400a to 400k. The ECC engine 320 may perform an ECC encoding operation on data to be stored in the nonvolatile memory devices 400a to 400k and may perform an ECC decoding operation on data read from the nonvolatile memory devices 400a to 400k.

The ROM 360 may store a variety of information, such as that used for the storage controller 300 to operate, in firmware.

The randomizer 340 may randomize data to be stored in one of the nonvolatile memory devices 400a to 400k. For example, the randomizer 340 may randomize data to be stored in one of the nonvolatile memory devices 400a to 400k by a word-line.

Data randomizing may include processing data such that program states of memory cells connected to a word-line have the same ratio. For example, if memory cells connected to one word-line are quadruple-level cells (QLC) each storing 4-bit data, each of the memory cells may have one of an erase state and first through fifteenth program states. In this case, the randomizer 340 may randomize data such that in memory cells connected to one word-line, the number of memory cells having the erase state, and each of the number of memory cells having the first through fifteenth program states may be substantially the same as one another. For example, memory cells in which randomized data is stored have program states of which the numbers are substantially equal to one another.

The randomizer 340 may randomize page data. An example of an operation of the randomizer 340 is described below. However, embodiments are not necessarily limited thereto. For example, the randomizer 340 may randomize data such that in memory cells connected to one word-line, the number of memory cells having the erase state and each of the number of memory cells having the first through fifteenth program states are approximately the same value. For example, memory cells in which randomized data is stored have program states of which the number may be similar to one another.

In an embodiment, when the number of memory cells having the erase state and each of the number of memory cells having the first through fifteenth program states are approximately the same value, this may mean that the number of the number of memory cells having the erase state and each of the number of memory cells having the first through fifteenth program states are within a particular threshold number of each other.

The buffer controller 380 may control an operation of the buffer memory 250.

The storage controller 300 may communicate with the host 100 through the host interface 350. For example, the host interface 350 may include Universal Serial Bus (USB), Multimedia Card (MMC), embedded-MMC, peripheral component interconnection (PCI), PCI-express, Advanced Technology Attachment (ATA), Serial-ATA, Parallel-ATA, small computer system interface (SCSI), enhanced small disk interface (ESDI), Integrated Drive Electronics (IDE), Mobile Industry Processor Interface (MIPI), Nonvolatile memory express (NVMe), Universal Flash Storage (UFS), or the like.

The storage controller 300 may communicate with the nonvolatile memory devices 400a to 400k through the memory interface 370. The storage controller 370 may include a data converter 373.

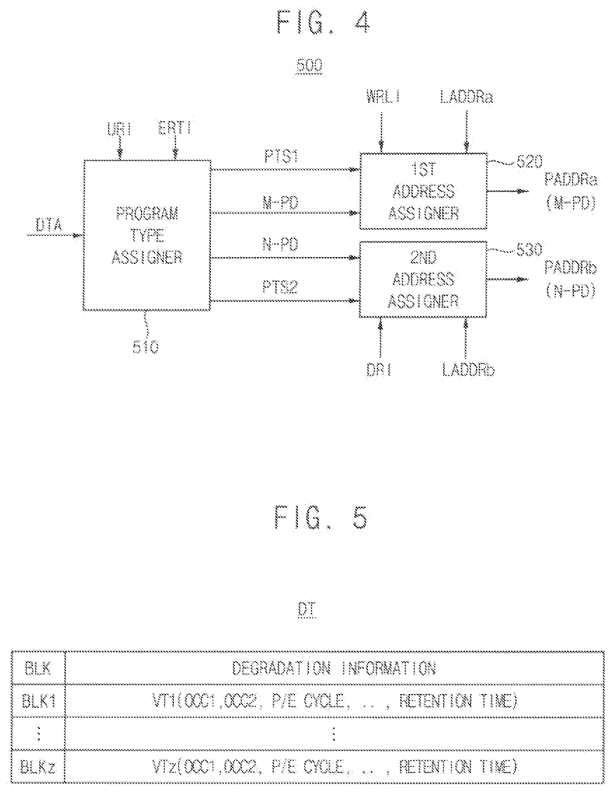

FIG. 4 illustrates an example of the program/address assigner in the storage controller of FIG. 3 according to an embodiment.

Referring to FIG. 4, the program/address assigner 500 may include a program type assigner 510, a first address assigner 520 and a second address assigner 530.

The program type assigner 510 may assign a program operation to be performed on the data DTA to be programmed in a plurality of memory blocks of the plurality of nonvolatile memory devices 400a to 400k, to one of a first program operation or a second program operation based on user request information URI of the data DTA and expected retention time information ETRI of the data DTA; and may assign M page data M-PD to the first program operation and may assign N page data N-PD to the second program operation. The program type assigner 510 may provide the first address assigner 520 with the M page data M-PD and a first program type signal PTS1 indicating that the program operation is assigned to the first program operation, and may provide the second address assigner 530 with the N page data N-PD and a second program type signal PTS2 indicating that the program operation is assigned to the second program operation. In an embodiment, the M page data M-PD may be also referred to as at least one first page of data and the N page data N-PD may be also referred to as at least one second page of data.

The expected retention time information ETRI may correspond to an expected storing time associated with the data DTA and the user request information URI may include at least one of a performance of the storage device, a latency associated with the program operation and/or a reliability of the data DTA.

The first address assigner 520 may receive the first program type signal PTS1 and the M page data PD-M, may select first memory blocks on which the first program operation is to be performed based on wear-leveling information WRLI of each of the memory blocks, may assign a logical address LADDRa of each of the first memory blocks to a first physical address PADDRa and may provide the physical address PADDRa and the M page data PD-M to the nonvolatile memory device 400a through the memory interface 370.

The wear-leveling information WRLI may include program/erase cycle information of each of the memory blocks.

The second address assigner 530 may receive the second program type signal PTS2 and the N page data PD-N, may select at least one second memory block for which the probability associated with degradation of memory cells is greatest from among the first memory blocks based on degradation information DRI of the first memory blocks, may assign a logical address LADDRb of the at least one second memory block to a second physical address PADDRb and may provide the second physical address PADDRb and the N page data PD-N to the nonvolatile memory device 400a through the memory interface 370.

The degradation information DRI of the first memory blocks may include at least one of charge loss information, ON cell count information, OFF cell count information, error count information, elapsed time information from completion of the first program operation of the M page data M-PD programmed in the first memory blocks. That is, the degradation information DRI of the first memory blocks may be associated with a probability of change (or, being moved) of threshold voltage distribution of memory cells in the first memory blocks due to the M page data M-PD programmed in the first memory blocks, the storage controller 300 may enhance and/or recover charge loss (or, moved threshold voltage distribution) by performing the second program operation on the at least one second memory block for which the probability of degradation of memory cells (e.g., memory cells being degraded) is greatest from among the first memory blocks.

When the first program operation is performed, memory cells of the first memory blocks store the M page data M-PD and when the second program operation is performed, memory cells of the at least one second memory block store the N page data N-PD.

Here, the first program operation may correspond to a triple-level cell (TLC) program operation to program memory cells of the first memory blocks to have an erase state and first through 2^{M}−1_th target program states, and the second program operation may correspond to a quadruple-level cell (QLC) program operation to program the memory cells of the at least one second memory block to have an erase state and first through 2^{N}−1_th target program states.

The program/address assigner 500 and/or the storage controller 300 may control the nonvolatile memory device 400a to select one of the first program operation on a third memory block in erase state and the second program operation on the second memory block and to perform the selected program operation after the first program operation on the first memory blocks is completed.

FIG. 5 illustrates an example of a degradation information table included in the on-chip memory in the storage controller of FIG. 3.

Referring to FIG. 5, a degradation information table DT may store degradation information and the degradation information may include information regarding the degradation in numbers and vector formats VT1 to VTz of each of a plurality of memory blocks BLK1 to BLKz. Here, z is a natural number greater than two. The information regarding the degradation may include at least one of an ON cell count OCC1, an OFF cell count OCC2, a program/erase cycle P/E CYCLE, retention time, and a number of error bits of read data.

Alternatively, the information regarding the degradation may include two or more ON cell counts obtained by using the read voltage levels different from one another or two or more OFF cell counts obtained by using the read voltage levels different from one another.

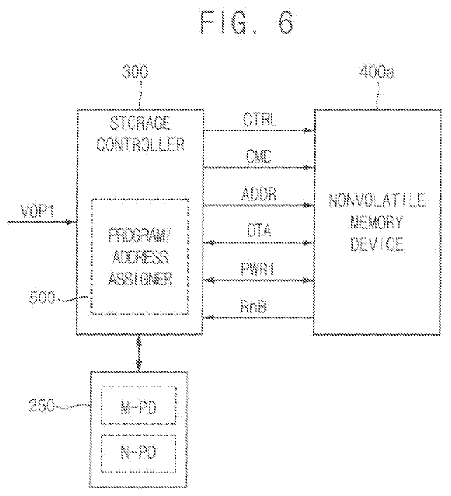

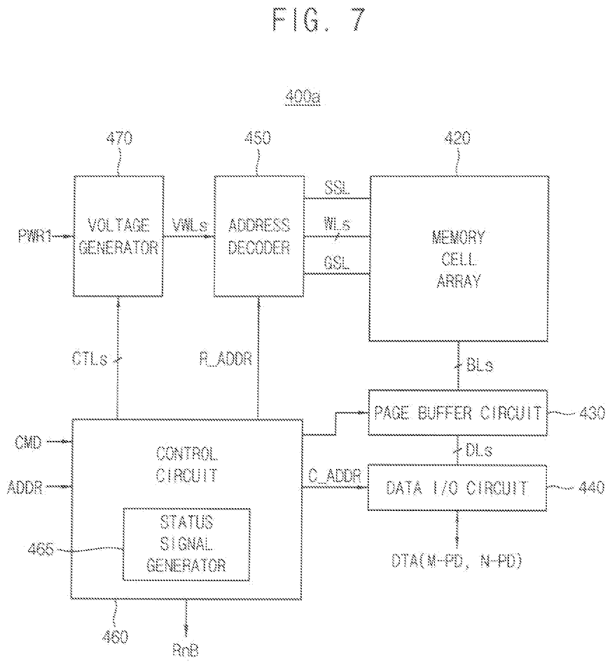

FIG. 6 illustrates a connection relationship between the storage controller and one nonvolatile memory device in the storage device of FIG. 1.

In FIG. 6, the buffer memory 250 connected to the storage controller 300 is also illustrated.

Referring to FIG. 6, the nonvolatile memory device 400a may operate based on the first operating voltage VOP1.

The nonvolatile memory device 400a may perform an erase operation, a program operation, and/or a write operation under control of the storage controller 300. The nonvolatile memory device 400a may receive a command CMD and an address ADDR through input/output lines from the storage controller 300 and may receive a data DTA through the buffer memory 250 for performing such operations. In addition, the nonvolatile memory device 400a may receive a control signal CTRL through a control line and receive a power PWR1 through a power line from the storage controller 300. In addition, the nonvolatile memory device 400a may provide the storage controller 300 with the data DTA using the buffer memory 250.

The data DTA may include the M page data M-PD and the N page data N-PD.

The storage controller 300 may include the program/address assigner 500. The program/address assigner 500, as described with reference to FIG. 4, may include the program type assigner 510 that may assign a program operation to be performed on the data DTA to be programmed in a plurality of memory blocks of the nonvolatile memory device 400a, to one of the first program operation and the second program operation based on the user request information URI of the data DTA and the expected retention time information ETRI of the data DTA, and may assign the M page data M-PD to the first program operation and may assign the N page data N-PD to the second program operation.

The buffer memory 250 may temporarily store the M page data M-PD from the host 100, may provide the M page data M-PD to the storage controller 300, may be released after the first program operation is completed, may temporarily store the N page data N-PD from the host 100 and may provide the N page data N-PD to the storage controller 300.

FIG. 7 illustrates the nonvolatile memory device of FIG. 6 according to an embodiment.

Referring to FIG. 7, the nonvolatile memory device 400a may include a memory cell array 420, an address decoder 450, a page buffer circuit 430, a data input/output (I/O) circuit 440, a control circuit 460, and a voltage generator 470.

The memory cell array 420 may be coupled to the address decoder 450 through a string selection line SSL, a plurality of word-lines WLs, and a ground selection line GSL. In addition, the memory cell array 420 may be coupled to the page buffer circuit 430 through a plurality of bit-lines BLs.

The memory cell array 420 may include a plurality of memory cells coupled to the plurality of word-lines WLs and the plurality of bit-lines BLs.

In an embodiment, the memory cell array 420 may be or include a three-dimensional memory cell array, which is formed on a substrate in a three-dimensional structure (e.g., a vertical structure). In this case, the memory cell array 420 may include a plurality of NAND strings that are vertically oriented such that at least one memory cell is located over another memory cell.

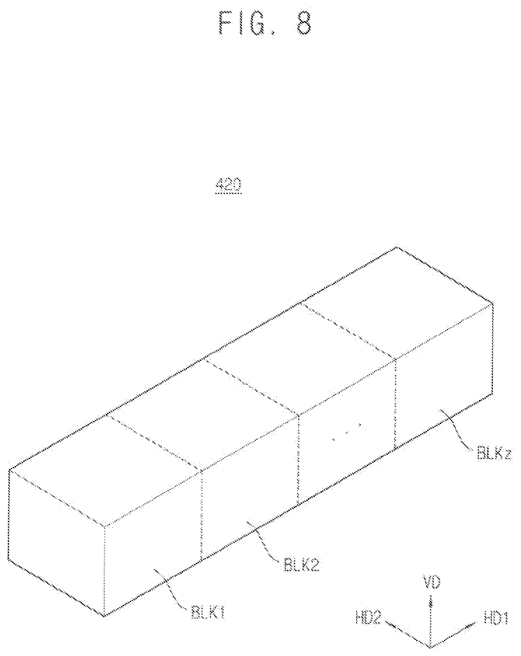

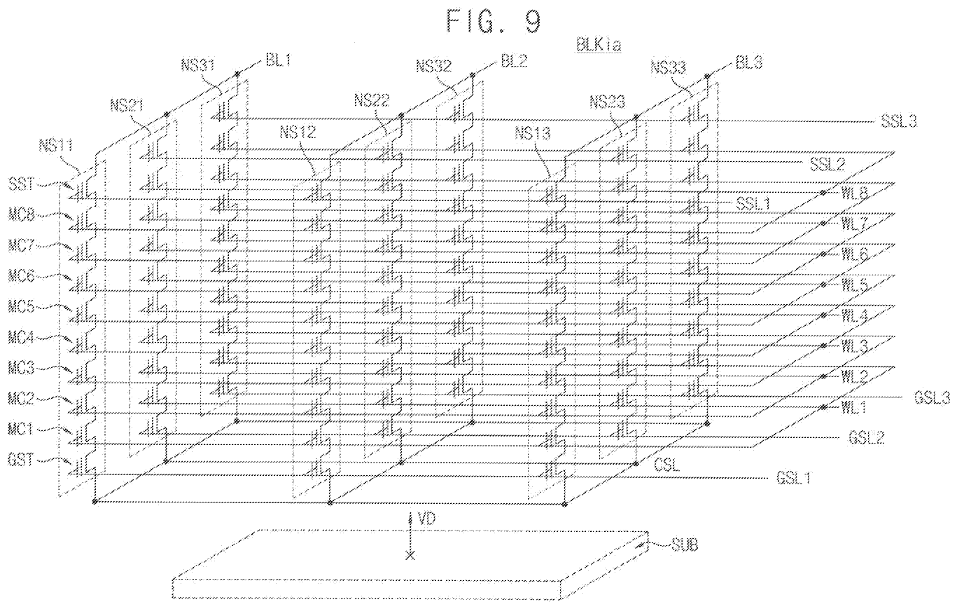

FIG. 8 illustrates an example of the memory cell array in the nonvolatile memory device of FIG. 7.

Referring to FIG. 8, the memory cell array 420 may include a plurality of memory blocks BLK1 to BLKz. The memory blocks BLK1 to BLKz extend along a first horizontal direction HD1, which may be for example an X-axis direction, a second horizontal direction HD2, which may be for example a Y-axis direction, and a vertical direction VD, which may be for example a Z-axis direction. In an embodiment, the memory blocks BLK1 to BLKz are selected by the address decoder 450 of FIG. of FIG. 7. For example, the address decoder 450 may select a memory block BLK corresponding to a block address among the memory blocks BLK1 to BLKz.

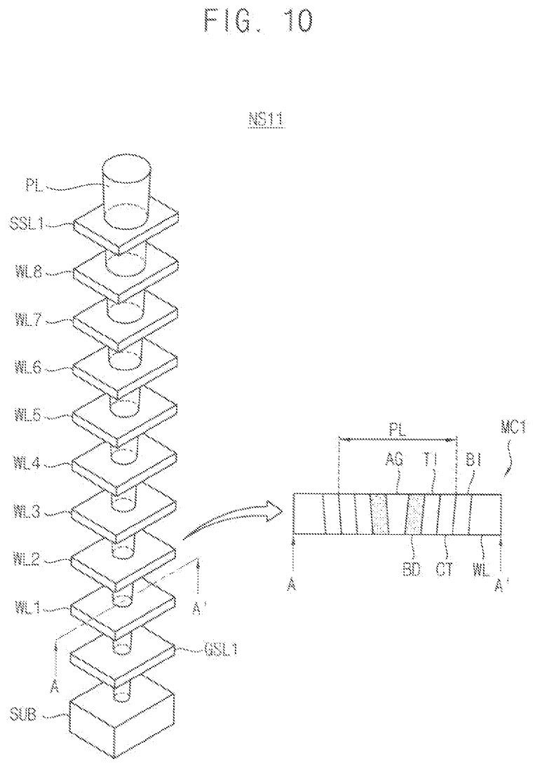

FIG. 9 illustrates one of the memory blocks of FIG. 8.

The memory block BLKia of FIG. 9 may be formed on a substrate SUB in a three-dimensional structure or in a vertical structure. For example, a plurality of memory cell strings included in a memory block BLKia may be formed in the vertical direction VD perpendicular to the substrate SUB.

Referring to FIG. 9, the memory block BLKia may include memory cell strings such as NAND strings NS11 to NS33 coupled between bit-lines BL1, BL2 and BL3 and a common source line CSL. Each of the memory cell strings NS11 to NS33 may include a string selection transistor SST, a plurality of memory cells MC1 to MC8, and a ground selection transistor GST.

The string selection transistor SST may be connected to corresponding string selection lines SSL1 to SSL3. The plurality of memory cells MC1 to MC8 may be connected to corresponding word-lines WL1 to WL8, respectively. The ground selection transistor GST may be connected to corresponding ground selection lines GSL1 to GSL3. The string selection transistor SST may be connected to corresponding bit-lines BL1, BL2 and BL3, and the ground selection transistor GST may be connected to the common source line CSL.

Word-lines (e.g., word-line WL1) having the same height may be commonly connected, and the ground selection lines GSL1 to GSL3 and the string selection lines SSL1 to SSL3 may be separated. In FIG. 9, the memory block BLKia is illustrated as being coupled to eight word-lines WL1 to WL8 and three bit-lines BL1 to BL3. However, embodiments are not necessarily limited thereto. In an embodiment, the memory cell array 420 may be coupled to any number of word-lines and bit-lines.

FIG. 10 illustrates an example of a structure of a NAND string in the memory block of FIG. 9.

Referring to FIGS. 9 and 10, a pillar PL is provided on the substrate SUB such that the pillar PL extends in a direction perpendicular to the substrate SUB, for example the vertical direction VD, to make contact with the substrate SUB. Each of the ground selection line GSL, the word lines WL1 to WL8, and the string selection lines SSL illustrated of FIG. 8 may be formed of a conductive material parallel with the substrate SUB, for example, a metallic material. The pillar PL may be in contact with the substrate SUB through the conductive materials forming the string selection lines SSL, the word lines WL1 to WL8, and the ground selection line GSL.

A sectional view taken along a line V-V′ is also illustrated of FIG. 10. In some an embodiment, a sectional view of a first memory cell MC1 corresponding to a first word line WL1 is illustrated. The pillar PL may include a cylindrical body BD. An air gap AG may be defined in the interior of the body BD.

The body BD may include P-type silicon and may be an area where a channel will be formed. The pillar PL may further include a cylindrical tunnel insulating layer TI surrounding the body BD and a cylindrical charge trap layer CT surrounding the tunnel insulating layer TI. A blocking insulating layer BI may be provided between the first word line WL and the pillar PL. The body BD, the tunnel insulating layer TI, the charge trap layer CT, the blocking insulating layer BI, and the first word line WL may constitute or be included in a charge trap type transistor that is formed in a direction perpendicular to the substrate SUB or to an upper surface of the substrate SUB. A string selection transistor SST, a ground selection transistor GST, and other memory cells may have the same structure as the first memory cell MC1.

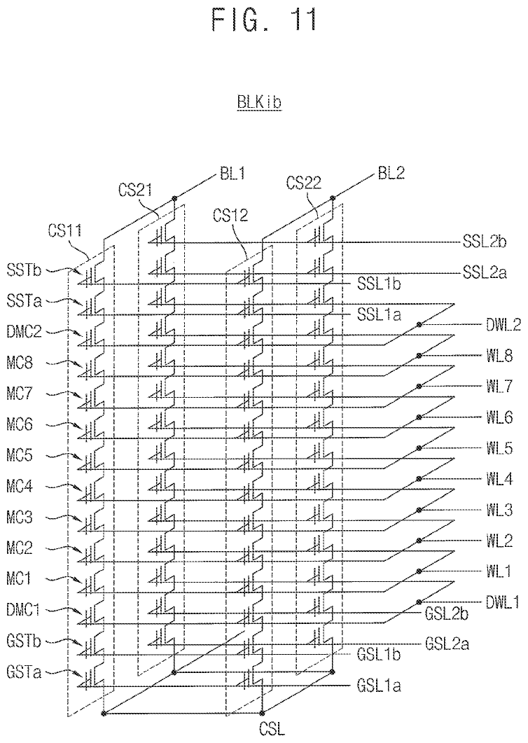

FIG. 11 illustrates one of the memory blocks of FIG. 8.

Referring to FIG. 11, a memory block BLKib may include a plurality of cell strings CS11, CS12, CS21 and CS22. The plurality of cell strings CS11, CS12, CS21 and CS22 may be arranged in a first horizontal direction (e.g., a row direction) and a second horizontal direction (e.g., a column direction). Each of the plurality of cell strings CS11, CS12, CS21 and CS22 may be referred to as a NAND cell string, without limitation thereto.

Cell strings positioned in the same column from among the plurality of cell strings CS11, CS12, CS21 and CS22 may be connected with the same bit-line. For example, the cell strings CS11 and CS21 may be connected with a first bit-line BL1, and the cell strings CS12 and CS22 may be connected with a second bit-line BL2. Each of the plurality of cell strings CS11, CS12, CS21 and CS22 may include a plurality of cell transistors. Each of the plurality of cell transistors may include a charge trap flash (CTF) memory cell. The plurality of cell transistors may be stacked in a height direction that is substantially perpendicular to a plane, such as substantially parallel to a semiconductor substrate, defined by the row direction and the column direction.

The plurality of cell transistors may be connected in series between a relevant bit-line (e.g., BL1 or BL2) and a common source line CSL. For example, the plurality of cell transistors may include string selection transistors SSTa and SSTb, dummy memory cells DMC1 and DMC2, memory cells MC1 to MC8, and ground selection transistors GSTa and GSTb. The serially-connected string selection transistors SSTa and SSTb may be provided between the serially-connected memory cells MC1 to MC8 and the relevant bit-line (e.g., BL1 and BL2). The serially-connected ground selection transistors GSTa and GSTb may be provided between the serially-connected memory cells MC1 to MC8 and the common source line CSL. In an embodiment, the second dummy memory cell DMC2 may be provided between the serially-connected string selection transistors SSTa and SSTb and the serially-connected memory cells MC1 to MC8, and the first dummy memory cell DMC1 may be provided between the serially-connected memory cells MC1 to MC8 and the serially-connected ground selection transistors GSTa and GSTb.

In the plurality of cell strings CS11, CS12, CS21 and CS22, memory cells positioned at substantially the same height from among the memory cells MC1 toMC8 may share the same word-line. For example, the first memory cells MC1 of the plurality of cell strings CS11, CS12, CS21 and CS22 may be positioned at the same height from the substrate and may share a first word-line WL1. The second memory cells MC2 of the plurality of cell strings CS11, CS12, CS21 and CS22 may be positioned at the same height from the substrate and may share a second word-line WL2.

In the plurality of cell strings CS11, CS12, CS21 and CS22, the dummy memory cells DMC1 or DMC2 positioned at the same height may share the same dummy word-line. For example, the first dummy memory cells DMC1 of the plurality of cell strings CS11, CS12, CS21 and CS22 may share a first dummy word-line DWL1, and the second dummy memory cells DMC2 of the plurality of cell strings CS11, CS12, CS21 and CS22 may share a second dummy word-line DWL2.

In the plurality of cell strings CS11, CS12, CS21 and CS22, string selection transistors positioned at the same height and the same row from among the string selection transistors SSTa and SSTb may be connected with the same string selection line. For example, the string selection transistors SSTb of the cell strings CS11 and CS12 may be connected with a string selection line SSL1b, and the string selection transistors SSTa of the cell strings CS11 and CS12 may be connected with a string selection line SSL1a. The string selection transistors SSTb of the cell strings CS21 and CS22 may be connected with a string selection line SSL2b, and the string selection transistors SSTa of the cell strings CS21 and CS22 may be connected with a string selection line SSL2a. In an embodiment, string selection transistors positioned at the same row from among the string selection transistors SSTa and SSTb of the plurality of cell strings CS11, CS12, CS21 and CS22 may share the same string selection line. For example, the string selection transistors SSTa and SSTb of the cell strings CS11 and CS12 may share a first string selection line, and the string selection transistors SSTa and SSTb of the cell strings CS21 and CS22 may share a second string selection line different from the first string selection line.

Ground selection transistors positioned at the same height and the same row from among the ground selection transistors GSTa and GSTb of the plurality of cell strings CS11, CS12, CS21 and CS22 may be connected with the same ground selection line. For example, the ground selection transistors GSTb of the cell strings CS11 and CS12 may be connected with a ground selection line GSL1b, and the ground selection transistors GSTa of the cell strings CS11 and CS12 may be connected with a ground selection line GSL1a. The ground selection transistors GSTb of the cell strings CS21 and CS22 may be connected with a ground selection line GSL2b, and the ground selection transistors GSTa of the cell strings CS21 and CS22 may be connected with a ground selection line GSL2a. In an embodiment, the ground selection transistors GSTa and GSTb of the plurality of cell strings CS11, CS12, CS21 and CS22 may share the same ground selection line. Alternatively, in the plurality of cell strings CS11, CS12, CS21 and CS22, ground selection transistors positioned at the same height from among the ground selection transistors GSTa and GSTb may share the same ground selection line. Alternatively, ground selection transistors positioned at the same row from among the ground selection transistors GSTa and GSTb of the plurality of cell strings CS11, CS12, CS21 and CS22 may share the same ground selection line.

Referring back to FIG. 7, the control circuit 460 may receive a command signal including the command CMD and an address signal including the address ADDR from the storage controller 300, and may control an erase loop, a program loop and/or a read operation of the nonvolatile memory device 400a based on the command CMD and the address ADDR. The program loop may include a program operation and a program verification operation. The erase loop may include an erase operation and an erase verification operation.

For example, the control circuit 460 may generate control signals CTLs, which are used for controlling the voltage generator 470, based on at least one of the command signal and the command CMD, and generate a row address R_ADDR and a column address C_ADDR based on at least one of the address signal and the address signal ADDR. The control circuit 460 may provide the row address R_ADDR to the address decoder 450 and may provide the column address C_ADDR to the data I/O circuit 440.

The address decoder 450 may be coupled to the memory cell array 420 through the string selection line SSL, the plurality of word-lines WLs, and the ground selection line GSL. During the program operation or the read operation, the address decoder 450 may determine one of the plurality of word-lines WLs as a first word-line, such as for a selected word-line, and determine the rest of the plurality of word-lines WLs except for the first word-line as unselected word-lines based on the row address R_ADDR.

The voltage generator 470 may generate word-line voltages VWLs, which are utilized for the operation of the nonvolatile memory device 400a, based on the control signals CTLs. The voltage generator 470 may receive the power PWR1 from the storage controller 300. The word-line voltages VWLs may be applied to the plurality of word-lines WLs through the address decoder 450.

For example, during the erase operation, the voltage generator 470 may apply an erase voltage to a well of the memory block and may apply a ground voltage to entire word-lines of the memory block. During the erase verification operation, the voltage generator 470 may apply an erase verification voltage to the entire word-lines of the memory block or sequentially apply the erase verification voltage to word-lines in a word-line basis.

For example, during the program operation, the voltage generator 470 may apply a program voltage to the first word-line and may apply a program pass voltage to the unselected word-lines. In addition, during the program verification operation, the voltage generator 470 may apply a program verification voltage to the first word-line and may apply a verification pass voltage to the unselected word-lines.

Furthermore, during the read operation, the voltage generator 470 may apply a read voltage to the first word-line and may apply a read pass voltage to the unselected word-lines.

The page buffer circuit 430 may be coupled to the memory cell array 420 through the plurality of bit-lines BLs. The page buffer circuit 430 may include a plurality of page buffers. In an embodiment, one page buffer may be connected to one bit-line. In an embodiment, one page buffer may be connected to two or more bit-lines.

The page buffer circuit 430 may temporarily store data to be programmed in a selected page or data read out from the selected page.

The data I/O circuit 440 may be coupled to the page buffer circuit 430 through data lines DLs. During program operation, the data I/O circuit 440 may receive the data DTA from the storage controller 300 and may provide the data DTA to the page buffer circuit 430 based on the column address C_ADDR received from the control circuit 460. The data DTA may include the M page data M-PD and the N page data N-PD.

During the read operation, the data I/O circuit 440 may provide the data DTA, which are stored in the page buffer circuit 430, to the storage controller 300 based on the column address C_ADDR received from the control circuit 460.

The control circuit 460 may control the page buffer circuit 430 and data I/O circuit 440.

The control circuit 460 may include a status signal generator 465 and the status signal generator 465 may generate a status signal RnB indicating whether each of the program operation, the erase operation and the read operation is completed or and/or is in progress.

The storage controller 300 may determine idle state or busy state of each of the nonvolatile memory devices 400a to 400k based on the status signal RnB.

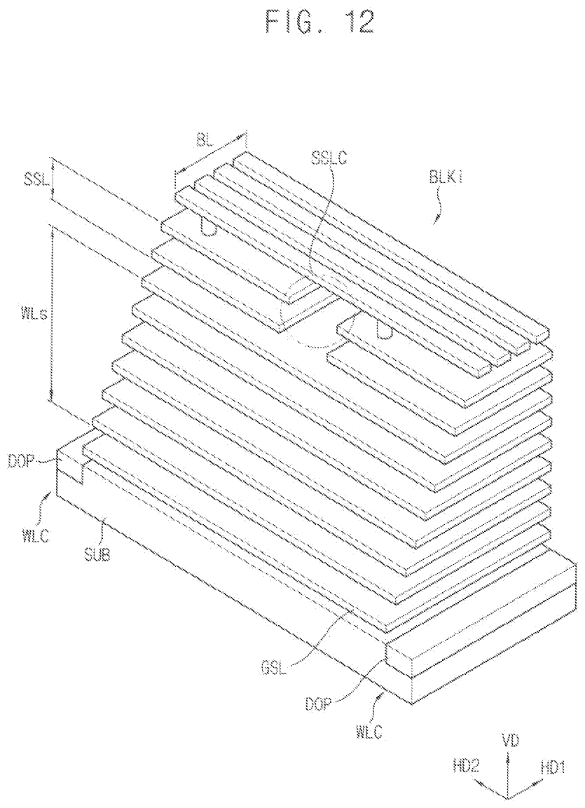

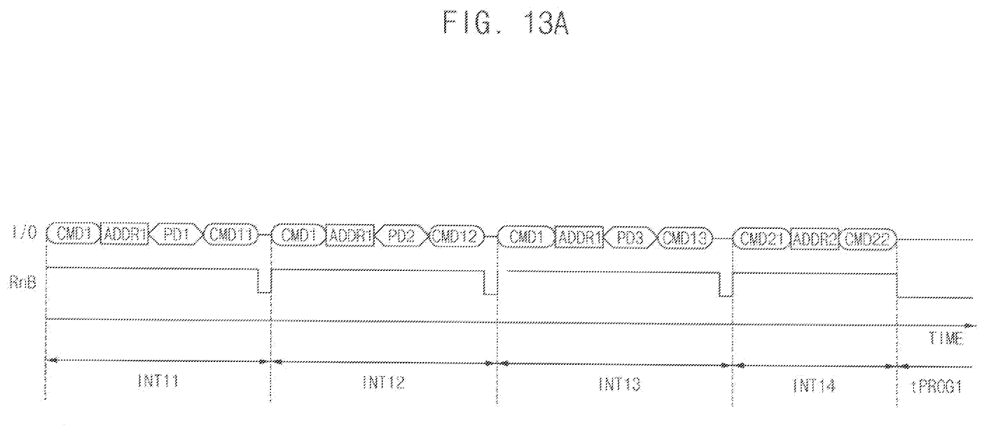

FIG. 12 illustrates one of the memory blocks of FIG. 8.

Referring to FIG. 12, a memory block BLKi (where i corresponds to one of 1 to z) may be implemented such that at least one ground selection line GSL, a plurality of word-lines WLs, and at least one string selection line SSL are stacked on a substrate between word-line cut regions WLC. Doping regions DOP may be formed in top portions of the substrate of the word-line cut regions WLC. The doping region may be used as common source lines CSL or common source nodes CSN to which a common source voltage is applied. The at least one string selection line SSL may be divided by a string selection line cut region SSLC extending in the first horizontal direction HD1.

A plurality of vertical channels or channel holes penetrate the at least one ground selection lines GSL, the plurality of word-lines WLs and the at least one string selection lines SSL. The at least one ground selection lines GSL, the plurality of word-lines WL and the at least one string selection lines SSL may be formed in the shape of planks. Bit-lines BL are connected to top surfaces of the channel holes.

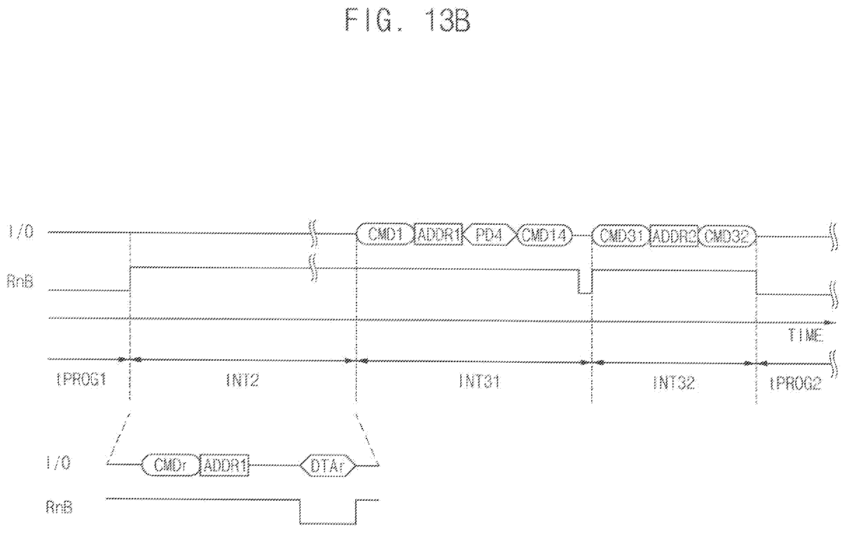

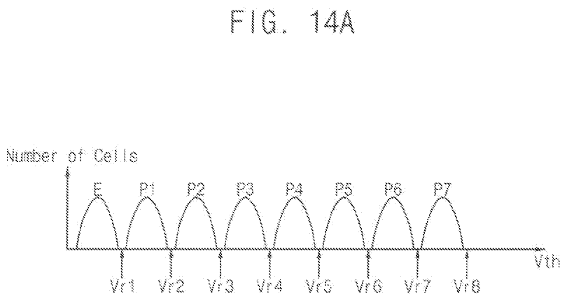

FIGS. 13A and 13B are each presented for describing a program operation of the storage device according to an embodiment.

Referring to FIGS. 6, 13A and 13B, the nonvolatile memory device 400a may receive first through third page data PD1, PD2 and PD3 from the storage controller 300. During an interval INT11, the nonvolatile memory device 400a may receive a command CMD1, a first address ADDR1, the first page data PD1, and a command CMD11 through I/O lines. The commands CMD1 and CMD11 may be a command set for setting up the first page data PD1. The nonvolatile memory device 400a may dump (e.g., transfer) the first page data PD1 in response to the command CMD11 and a status signal RnB may be in a busy state while the first page data PD1 is dumped.

During an interval INT12, the nonvolatile memory device 400a may receive the command CMD1, a second address ADDR2, the second page data PD2, and a command CMD12 through the I/O lines. The commands CMD1 and CMD12 may be a command set for setting up the second page data PD2. The nonvolatile memory device 400a may dump (e.g., transfer) the second page data PD2 in response to the command CMD12 and the status signal RnB may be in a busy state while the second page data PD3 is dumped.

During an interval INT13, the nonvolatile memory device 400a may receive the command CMD1, a third address ADDR3, the third page data PD3, and a command CMD13 through the I/O lines. The commands CMD1 and CMD13 may be a command set for setting up the third page data PD3. The nonvolatile memory device 400a may dump (e.g., transfer) the third page data PD3 in response to the command CMD13 and the status signal RnB may be in a busy state while the third page data PD3 is dumped.

During an interval INT14, the nonvolatile memory device 400a may receive the command CMD1 and a second address ADDR2, and a command CMD14 through the I/O lines. The commands CMD1 and CMD14 may be a command set for initiating a program operation. The second address ADDR2 may include information about a program order.

During a program time tPROG1, the nonvolatile memory device 400a may perform a first program operation to program the first, second, and third page data PD1, PD2, and PD3 in response to the command CD22. During the program time tPROG1, the status signal RnB may be in a busy state (e.g., in a low state).

An interval INT2 may elapsed after the first program operation is completed. During the interval INT2, the nonvolatile memory device 400a may receive a read command CMDr and the first address ADDR1, may read the first, second, and third pages PD1, PD2, and PD3 from the memory cell array 420 in response to the read command CMDr as a read data DTAr and may provide the CMDr to the storage controller 300. During the read data DTAr are read from the memory cell array 420 the status signal RnB may be in a busy state (e.g., in a low state).

The storage controller 300 may determine degradation state of the first memory blocks in which the first through third program data PD1, PD2 and PD3 are programmed, based on the read data DTAr may select a second memory block for which the probability of memory cells being degraded is greatest from among the first memory blocks.

During an interval INT31, the nonvolatile memory device 400a may receive the command CMD1, the first address ADDR1, a fourth page data PD4, and a command CMD14 through the I/O lines. The commands CMD1 and CMD14 may be a command set for setting up the fourth page data PD4. The nonvolatile memory device 400a may dump (e.g., transfer) the fourth page data PD4 in response to the command CMD14 and the status signal RnB may be in a busy state while the fourth page data PD4 is dumped.

During an interval INT32, the nonvolatile memory device 400a may receive a command CMD31 and the second ADDR2, and a command CMD32 through the I/O lines. The commands CMD31 and CMD32 may be a command set for initiating a program operation. The second address ADDR2 may include information about a program order.

During a program time tPROG2, the nonvolatile memory device 400a may perform a second program operation to program the fourth page data PD4 on the second memory block in response to the command CD32. During the program time tPROG2, the status signal RnB may be in a busy state (e.g., in a low state).

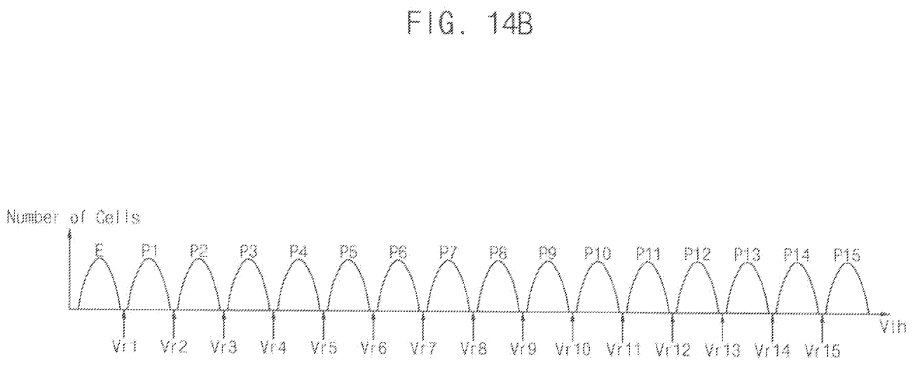

FIG. 14A shows a threshold voltage distribution of memory cells when a memory cell included in the memory cell array of FIG. 7 is a 3-bit TLC.

Referring to FIG. 14A, a horizontal axis represents a threshold voltage Vth and the vertical axis represents the number of memory cells. When each of the memory cells is a 3-bit TLC programmed to store 3 bits, the memory cell may have one from among an erase state E and first through seventh program states P1 through P7. When a memory cell is a multi-level cell, unlike a single-level cell, because an interval between threshold voltages distributions is small, a small change in the threshold voltage Vth may cause a large problem.

A first read voltage Vr1 has a voltage level between a distribution of a memory cell having the erase state E and a distribution of a memory cell having the first program state P1. Each of second through seventh read voltages Vr2 through Vr7 have a voltage level between distributions of memory cells having adjacent program states.

FIG. 14B shows a threshold voltage distribution of memory cells when a memory cell included in the memory cell array of FIG. 7 is a 4-bit QLC.

Referring to FIG. 14B, a horizontal axis represents a threshold voltage Vth and the vertical axis represents the number of memory cells. When each of the memory cells is a 4-bit QLC programmed to store 4 bits, the memory cell may have one from among an erase state E and first through fifteenth program states P1 through P15. When a memory cell is a multi-level cell, unlike a single-level cell, because an interval between threshold voltages distributions is small, a small change in the threshold voltage Vth may cause a large problem.

A first read voltage Vr1 has a voltage level between a distribution of a memory cell having the erase state E and a distribution of a memory cell having the first program state P1. Each of second through fifteenth read voltages Vr2 through Vr15 have a voltage level between distributions of memory cells having adjacent program states.

In an embodiment, assuming that the first read voltage Vr1 is applied, when a memory cell is turned on, data ‘1’ may be stored, and when the memory cell is turned off, data ‘0’ may be stored. However, embodiments are not necessarily limited thereto. For example, in an embodiment, assuming that the first read voltage Vr1 is applied, when a memory cell is turned on, data ‘0’ may be stored, and when the memory cell is turned off, data ‘1’ may be stored. As such, a logic level of data may vary according to embodiments of the present disclosure.

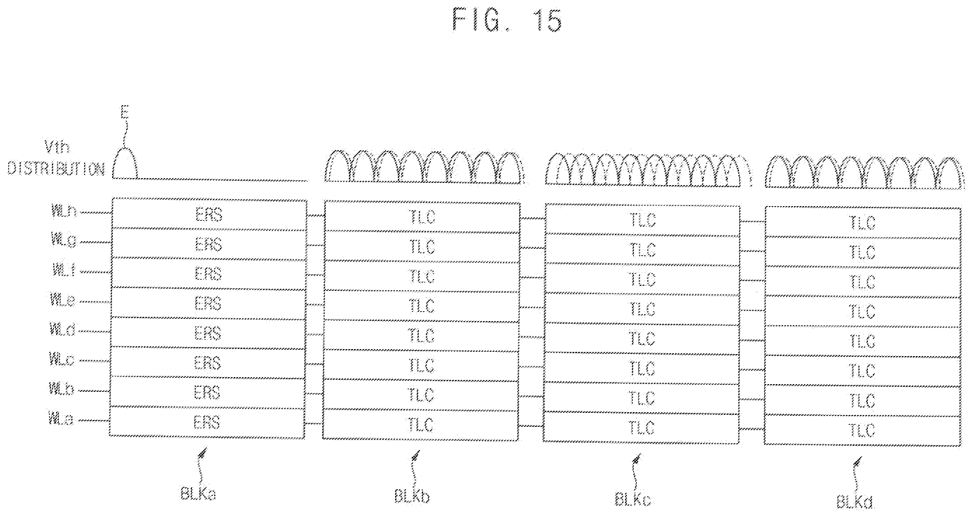

FIG. 15 illustrates a portion of a plurality of memory blocks of FIG. 8 according to an embodiment.

In FIG. 15, there are illustrated first memory blocks BLKa, BLKb, BLKc and BLKd coupled to a plurality of word-lines WLa, WLb, WLc, WLd, WLe, WLf, WLg and WLh. Memory cells of the memory block BLKa are in erase state ERS, and the first program operation has been performed on the memory cells of the memory blocks BLKb, BLKc and BLKd. In addition, of FIG. 15, bold lines represent original (e.g., unmoved) threshold voltage distributions of the memory cells of the memory blocks BLKb, BLKc and BLKd and dotted line represent moved threshold voltage distributions of the memory cells of the memory blocks BLKb, BLKc and BLKd. The control circuit 460 of FIG. 7 may sequentially perform the first program operation on the memory cells of the memory blocks BLKb, BLKc and BLKd under control of the program/address assigner 500 of FIG. 4. Therefore, the memory cells in each of the memory blocks BLKb, BLKc and BLKd have 8 threshold voltage states as TLC. The memory block BLKa corresponds to a memory block in erase state and the memory blocks BLKb, BLKc and BLKd correspond to second memory blocks.

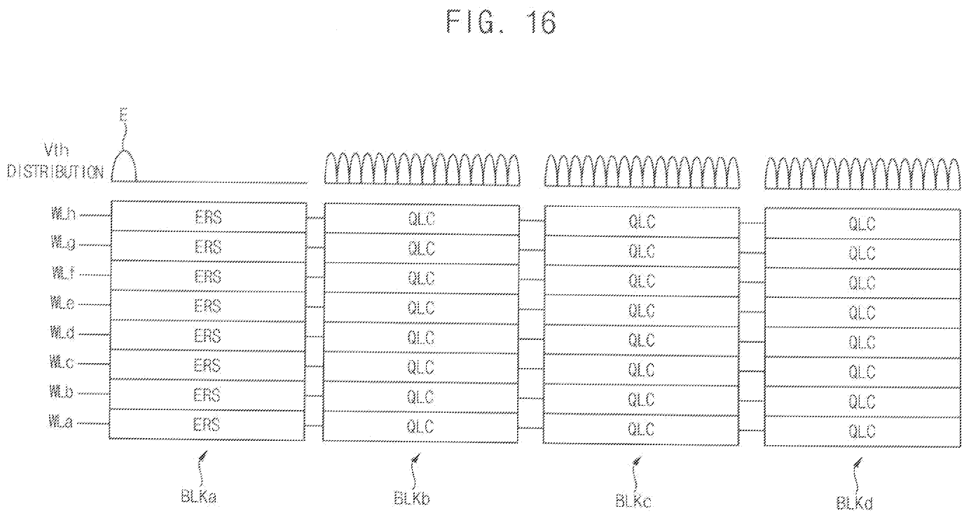

FIG. 16 illustrates that a second program operation is performed on a portion of the memory blocks of FIG. 15 according to an embodiment.

Referring to FIGS. 15 and 16, the control circuit 460 of FIG. 7 performs the second program operation on the second memory blocks BLKb, BLKc and BLKd except the memory block BLKa in erase state and memory cells in each of the memory blocks BLKb, BLKc and BLKd have 16 threshold voltage states as QLC. That is, the memory cells in the memory blocks BLKa, BLKb, BLKc and BLKd have the erase state and first through fifteenth (target) program states.

The program/address assigner 500 of FIG. 4 may perform the second program operation to program the fourth program data PD4 in the second memory blocks BLKb, BLKc and BLKd, in response to charge loss of the memory cells in the second memory blocks BLKb, BLKc and BLKd being greater than a first reference value, in response to data retention time of the second memory blocks BLKb, BLKc and BLKd being smaller than a second reference value or in response to requested performance included in the user request information URI being smaller than a third reference value.

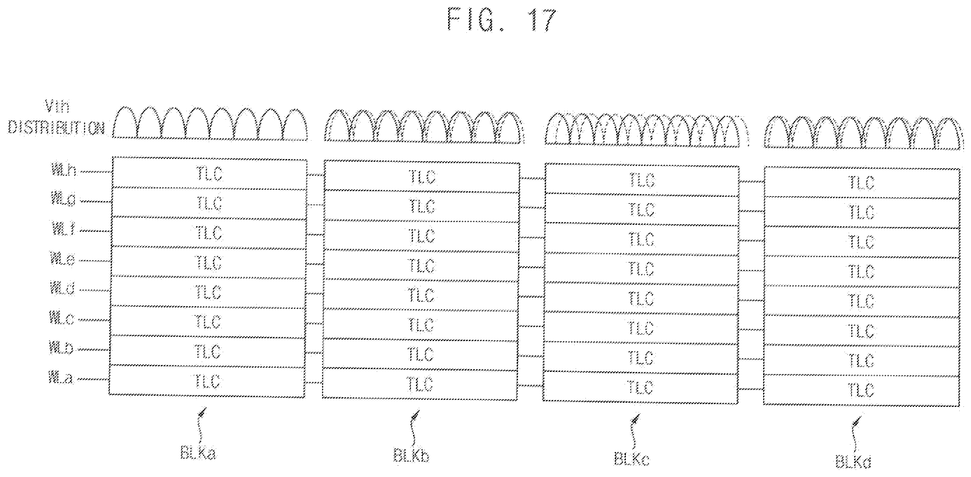

FIG. 17 illustrates that a first program operation is performed on a portion of the memory blocks of FIG. 15 according to an embodiment.

Referring to FIGS. 15 and 17, the control circuit 460 of FIG. 7 performs the first program operation on the memory block BLKa in erase state and memory cells in each of the memory blocks BLKa, BLKb, BLKc and BLKd have 8 threshold voltage states as TLC. That is, the memory cells in the memory blocks BLKa, BLKb, BLKc and BLKd have the erase state and first through fifteenth (target) program states. In FIG. 17, bold lines represent original (e.g., unmoved) threshold voltage distributions of the memory cells of the memory blocks BLKb, BLKc and BLKd and dotted line represent moved threshold voltage distributions of the memory cells of the memory blocks BLKb, BLKc and BLKd.

The program/address assigner 500 of FIG. 4 may perform the first program operation to program the first through third program PD1, PD2 and PD3 in a third memory block BLKa in erase state in response to charge loss of the memory cells in the second memory blocks BLKb, BLKc and BLKd being smaller than the first reference value, in response to data retention time of the second memory blocks BLKb, BLKc and BLKd being greater than the second reference value or in response to requested performance included in the user request information URI being greater than the third reference value.

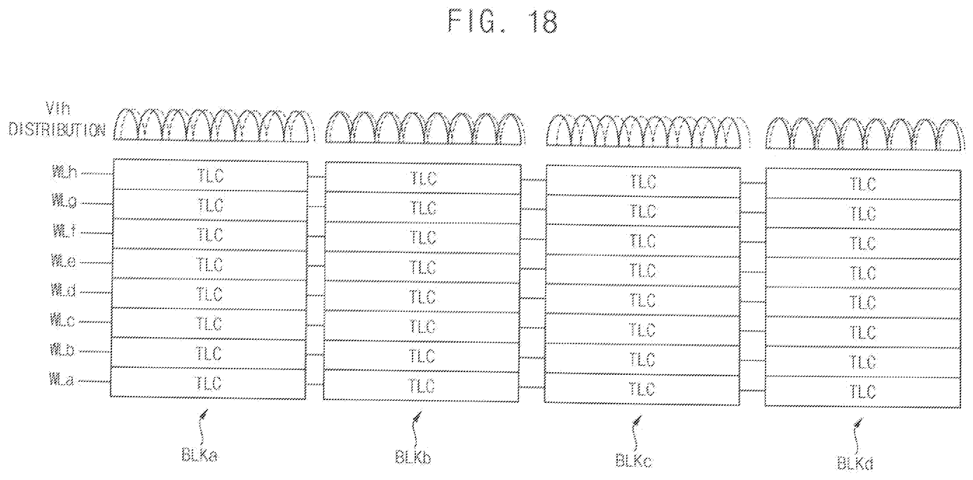

FIG. 18 illustrates a portion of a plurality of memory blocks of FIG. 8 according to an embodiment.

In FIG. 18, the illustrated memory blocks BLKa, BLKb, BLKc and BLKd are coupled to a plurality of word-lines WLa, WLb, WLc, WLd, WLe, WLf, WLg and WLh. FIG. 18 illustrates that a specific time interval elapses after the first program operation on the memory blocks BLKa, BLKb, BLKc and BLKd is completed. Memory cells of the memory blocks BLKa, BLKb, BLKc and BLKd have 8 threshold voltage states. In FIG. 18, bold lines represent original (e.g., unmoved) threshold voltage distributions of the memory cells of the memory blocks BLKa, BLKb, BLKc and BLKd, and dotted line represent moved threshold voltage distributions of the memory cells of the memory blocks BLKa, BLKb, BLKc and BLKd. A change of the threshold voltage distributions of the memory cells of the memory block BLKc are greater than a change of the threshold voltage distributions of the memory cells of the memory blocks BLKa, BLKb and BLKd.

The storage controller 300, and/or the control circuit 460, may determine the change of the threshold voltage distributions using or based on an ON cell count of each of the memory blocks BLKa, BLKb, BLKc and BLKd by applying a default read voltage discriminating the erase state and a first or target program state to the plurality word-lines WLa, WLb, WLc, WLd, WLe, WLf, WLg and WLh of the first memory blocks, and by reading data from the memory cells of the memory blocks BLKa, BLKb, BLKc and BLKd.

The storage controller 300, or the control circuit 460, may determine the change of the threshold voltage distributions using or based on an OFF cell count of each of the memory blocks BLKa, BLKb, BLKc and BLKd by applying a seventh read voltage discriminating a sixth (target) program state and a seventh (target) program state to the plurality word-lines WLa, WLb, WLc, WLd, WLe, WLf, WLg and WLh of the memory blocks BLKa, BLKb, BLKc and BLKd and by reading data from the memory cells of the memory blocks BLKa, BLKb, BLKc and BLKd. The seventh read voltage may be referred to as a default read voltage and a sixth or target program state and a seventh target program state may be referred to as a 2^{M}−2_th target program state and a 2^{M}−1_th target program state, respectively, where M may be three, for example.

The storage controller 300 and/or the control circuit 460 may determine the change of the threshold voltage distributions by error count of each of the memory blocks BLKa, BLKb, BLKc and BLKd by obtaining a read data by applying a read voltage to the plurality word-lines WLa, WLb, WLc, WLd, WLe, WLf, WLg and WLh of the memory blocks BLKa, BLKb, BLKc and BLKd after the first program operation is completed and by obtaining the error count by performing an error correction code (ECC) decoding on the read data.

The storage controller 300 and/or the control circuit 460 may determine the change of the threshold voltage distributions by reading time stamp information stored in each of the memory blocks BLKa, BLKb, BLKc and BLKd when the first program operation on the memory blocks BLKa, BLKb, BLKc and BLKd is completed.

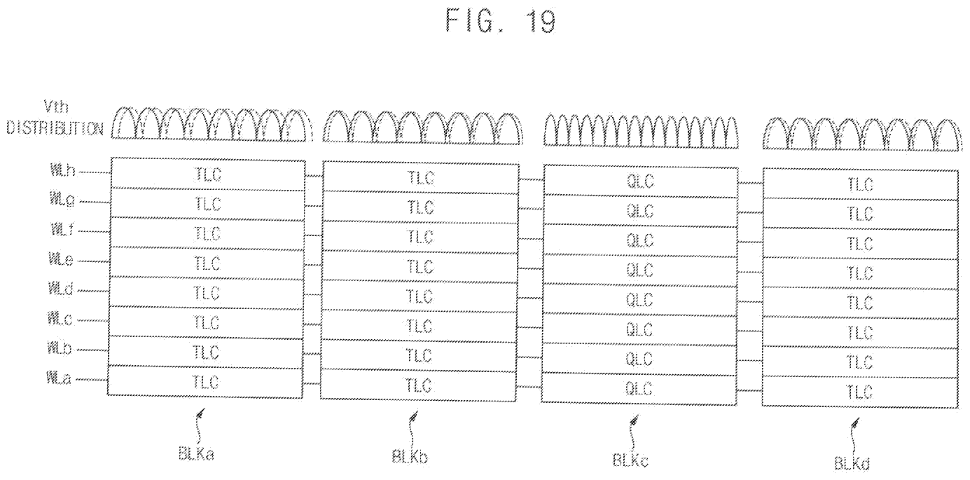

FIG. 19 illustrates that a second program operation is performed on a portion of the memory blocks of FIG. 18 according to an embodiment.

Referring to FIGS. 18 and 19, the control circuit 460 of FIG. 7 performs the second program operation on the memory block BLKc for which the probability of data loss, or degradation of memory cells, is greatest from among the memory blocks BLKa, BLKb, BLKc and BLKd, and the memory cells in the memory block BLKc have 16 threshold voltage states as QLC. Therefore, the storage controller 300 may enhance and/or recover charge loss, or moved threshold voltage distribution, of the memory cells of the memory block BLKc.

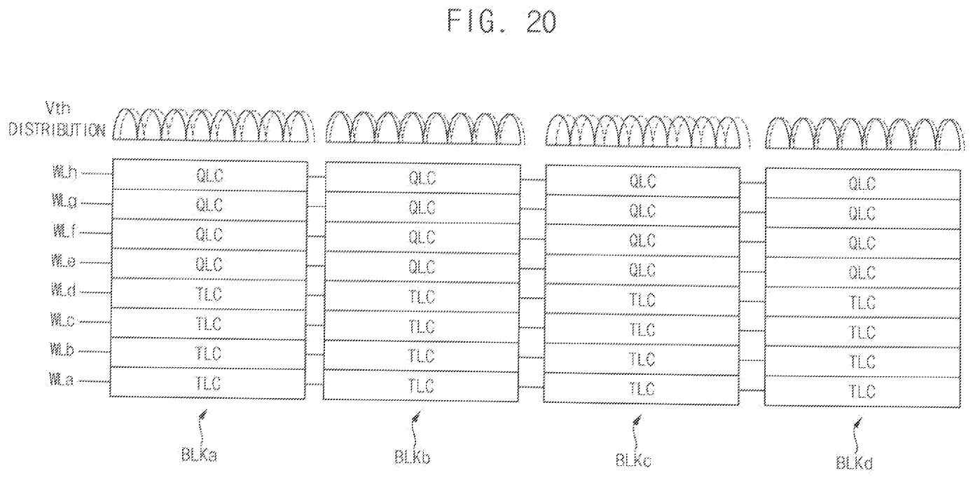

FIG. 20 illustrates a portion of a plurality of memory blocks of FIG. 8 according to an embodiment.

In FIG. 20, the illustrated memory blocks BLKa, BLKb, BLKc and BLKd are coupled to a plurality of word-lines WLa, WLb, WLc, WLd, WLe, WLf, WLg and WLh. FIG. 20 illustrates that a specific time interval elapses after the first program operation is performed on memory cells coupled to the word-lines WLa, WLb, WLc, and WLd of the memory blocks BLKa, BLKb, BLKc and BLKd and the second program operation is performed on memory cells coupled to the word-lines WLe, WLf, WLg and WLh of the memory blocks BLKa, BLKb, BLKc and BLKd. Therefore, the memory cells coupled to the word-lines WLa, WLb, WLc, and WLd of the memory blocks BLKa, BLKb, BLKc and BLKd have 8 threshold voltage states as TLC and the memory cells coupled to the word-lines WLe, WLf, WLg and WLh of the memory blocks BLKa, BLKb, BLKc and BLKd have 16 threshold voltage states as QLC.

In FIG. 20, bold lines represent original (e.g., unmoved) threshold voltage distributions of the memory cells of the memory blocks BLKa, BLKb, BLKc and BLKd, and dotted lines represent moved threshold voltage distributions of the memory cells of the memory blocks BLKa, BLKb, BLKc and BLKd. A change of the threshold voltage distributions of the memory cells of the memory block BLKc are greatest from among the memory blocks BLKa, BLKb, BLKc and BLKd.

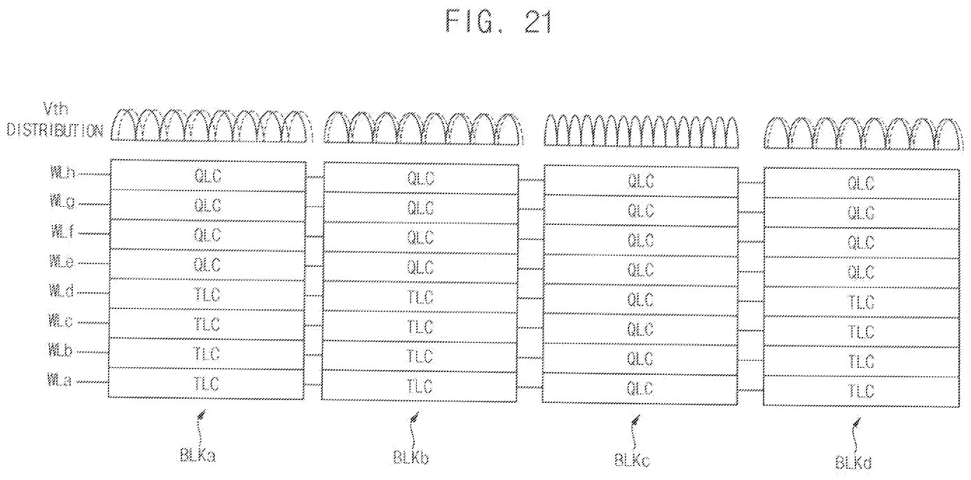

FIG. 21 illustrates that a second program operation is performed on a portion of the memory blocks of FIG. 20 according to an embodiment.

Referring to FIGS. 20 and 21, the control circuit 460 of FIG. 7 performs the second program operation on the memory cells coupled to the word-lines WLa, WLb, WLc, and WLd of the memory blocks BLKa, BLKb, BLKc and BLKd for which the probability of data loss, or degradation of memory cells, is greatest from among the memory blocks BLKa, BLKb, BLKc and BLKd, and the memory cells in the memory block BLKc have 16 threshold voltage states as QLC. Therefore, the storage controller 300 may enhance and/or recover charge loss, or moved threshold voltage distribution, of the memory cells of the memory block BLKc.

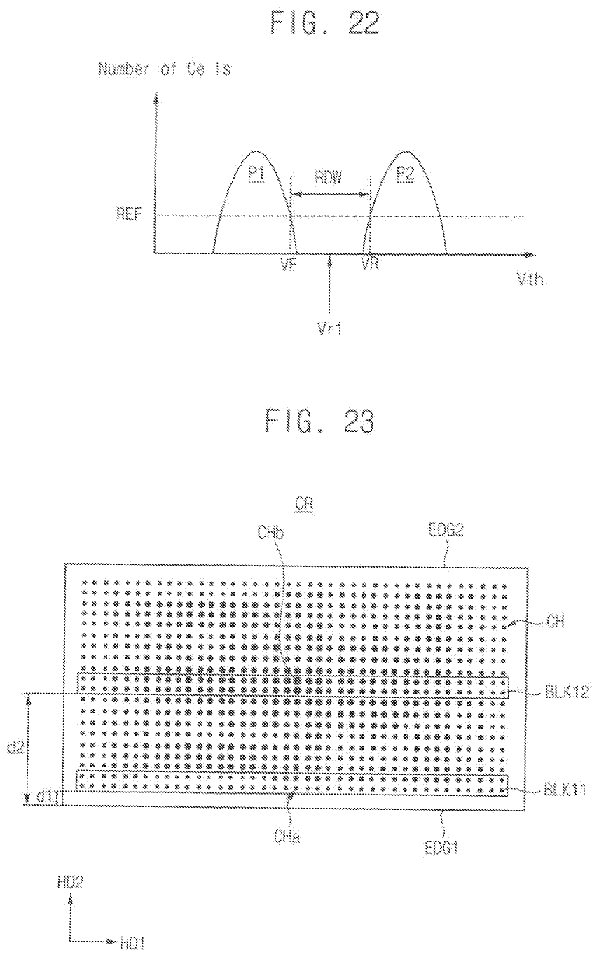

FIG. 22 shows enlarged first and second program states of FIG. 14A.

Referring to FIG. 22, a read window RDW between the first and second program states P1 and P2 may be defined as a difference between a fall voltage VF corresponding to the first program state P1 and a rise voltage VR corresponding to the second program state P2. Here, the fall voltage VF may represent a threshold voltage where the number of “OFF” cells corresponds to a reference number REF, based on an “OFF” cell count result for memory cells programmed to the first program state P1. The rise voltage VR may represent a threshold voltage where the number of “OFF” cells corresponds to the reference number REF, based on an “OFF” cell count result for memory cells programmed to the second program state P2. A read voltage Vr2 for determining the second program state P2 should have a voltage level within the read window RWD, and in order to decrease a read error, the read window RWD should be sufficiently widely secured.

FIG. 23 illustrates a cell region in which the memory cell array of FIG. 7 is formed according to an embodiment.

Referring to FIG. 23, a cell region CR includes a plurality of channel holes CH.

A channel hole size, for example, a channel hole diameter, may be varied according to positions within the cell region CR. For example, channel holes CH adjacent to the first and second edges EDG1 and EDG2 have a low peripheral density, and thus may have a different diameter from those of other channel holes CH. A memory block BLKa may be adjacent to the second edge EDG2, and may be spaced apart from the second edge EDG2 by a first distance d1. A memory block BLKb need not be adjacent to the first and second edges EDG1 and EDG2, may be in a center of the cell region CR, and may be spaced apart from the second edge EDG2 by a second distance d2. The second distance d2 may be greater than the first distance d1. A first diameter D1 of a first channel hole CHa included in the memory block BLKa may be smaller than a second diameter D2 of a second channel hole CHb included in the memory block BLKb.

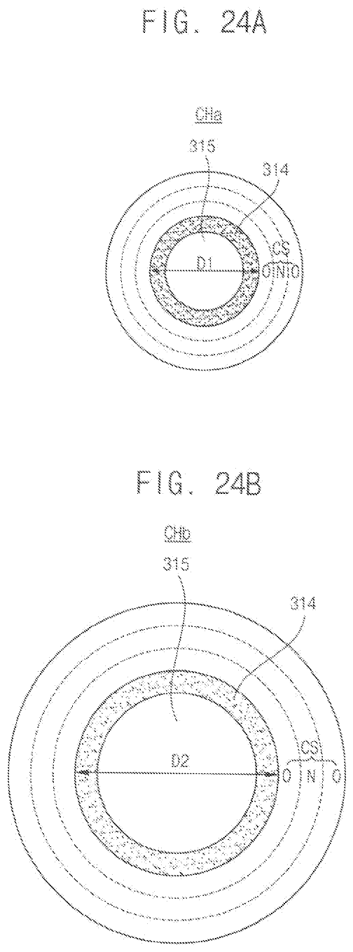

FIGS. 24A and 24B illustrate cross-sections of strings of the memory blocks BLKa and BLKb of FIG. 23, respectively.

Referring to FIG. 24A, a pillar including a channel layer 314 and an internal layer 315 may be formed in the first channel hole CHa included in the memory block BLKa, and a charge storage layer CS may be formed around the first channel hole CHa, and the charge storage layer CS may have an (oxide-nitride-oxide) ONO structure.

Referring to FIG. 24B, a pillar including a channel layer 314 and an internal layer 315 may be formed in the second channel hole CHb included in the memory block BLKb, and a charge storage layer CS may be formed around the second channel hole CHb, and the charge storage layer CS may have an ONO structure.

In an embodiment, a thickness of the charge storage layer CS included in the memory block BLKb may be different from a thickness of the charge storage layer CS included in the memory block BLKa. Characteristics of memory cells may vary due to the difference in the channel hole diameters. For example, in a NAND flash nonvolatile memory device having a gate all around structure in which a gate electrode is disposed around a circumference of a channel hole, if a channel hole diameter is reduced, the magnitude of an electric field formed between a gate electrode and a channel layer 314 is increased. Thus, program and erase speeds of a memory cell having a relatively small channel hole diameter like the first channel hole CHa may be higher than those of a memory cell having a relatively large channel hole diameter like the second channel hole CHb.

Referring back to FIG. 23, a memory block is formed in the cell region CR to include all memory cells corresponding to one page in the first horizontal direction HD1, that is, in a word-line direction, and to include some strings in the second horizontal direction HD2, that is, in a bit-line direction. Thus, each memory block extends in the first horizontal direction HD1, and channel hole sizes, that is, channel hole diameters may differ in units of memory blocks. Thus, program and erase speeds of memory cells included in the memory block BLKa may be higher than program and erase speeds of memory cells included in the memory block BLKb.

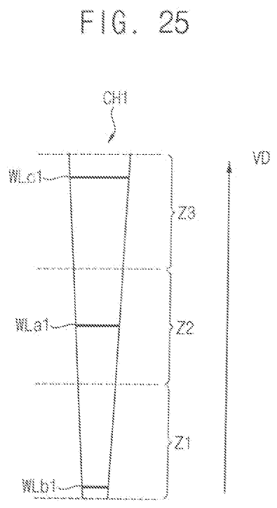

FIG. 25 illustrates an example of a vertical structure of one of the channel holes of FIG. 23.

Referring to FIG. 25, a channel hole CH1 corresponding to a string included in a nonvolatile memory device is illustrated. As described above, the channel hole CH1 is formed by etching portions of gate electrodes and insulation layers stacked on a substrate, and thus, the channel hole CH1 may be a tapered etching profile where a diameter of the channel hole CH1 becomes downwardly smaller. Thus, a diameter of the channel hole CH1 may be smaller towards the substrate.

In an embodiment, the channel hole CH1 may be divided into three zones according to channel hole diameters. For example, a zone in which a channel hole diameter is smaller than a first value may be referred to as a first zone Z1, and a zone in which a channel hole diameter is equal to or greater than the first value and smaller than a second value may be referred to as a second zone Z2, and a zone in which a channel hole diameter is equal to or greater than the second value and smaller than a third value may be referred to as a third zone Z3. Therefore, characteristic of memory cells included in one channel hole may be different according to positions along the vertical direction VD.

A word-line WLb1 is provided in the first zone Z1, a word-line Wla1 is provided in the second zone Z2, and a word-line WLc1 is provided in the third zone Z3. Because the word-line WLb1 is adjacent to a lower edge of the channel hole CH1, and the word-line WLb1 is adjacent to a ground selection line or the substrate, there might be a possibility of a bridge occurring between the word-line WLb1 and the channel. When the bridge occurs between the word-line WLb and the channel, a current leakage may occur through the bridge and program/read operation and erase operation may operate abnormally in the word-line WLb1 due to the bridge.

Because the word-line WLc1 is adjacent to an upper edge of the channel hole CH1, and the word-line WLc1 is adjacent to a string selection line or the substrate, there might be a possibility of a bridge occurring between the word-line WLc1 and the channel.

Error occurrence probability of pages coupled to the word-line WLc1, which is adjacent to an upper edge of the channel hole CH1, or coupled to the word-line WLb1, which is adjacent to the lower edge of the channel hole CH1, may be greater than an error occurrence probability of pages coupled to the word-line Wla1, which is disposed at a center region of the channel hole CH1.

FIGS. 22 through 25 relate to examples in which a probability of degradation of memory cells coupled to a word-line may be different based on a location of the word-line.

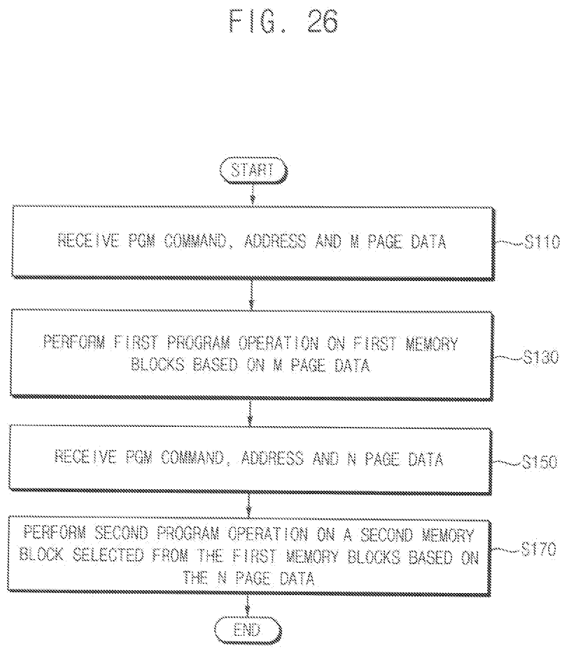

FIG. 26 illustrates a method of operating a storage device according to an embodiment.

Referring to FIGS. 3 through 26, a method is provided of operating a storage device 200 including a nonvolatile memory device 400a and a storage controller 300 to control the nonvolatile memory device 400a which includes a memory cell array, where the memory cell array includes a plurality of word-lines stacked on a substrate, a plurality of memory cells provided in a plurality of channel holes extending in a vertical direction with respect to the substrate and a word-line cut region extending in a first horizontal direction and dividing the plurality of word-lines into a plurality of memory blocks.

According to the method, the nonvolatile memory device 400a receives a first program command, a physical address and an M page data M-PD from the storage controller 300 (operation S110).

The nonvolatile memory device 400a performs a first program operation on a first memory block of the memory cell array based on the M page data PD-M, expected retention time information of the M page data PD-M and user request information associated with the M page data PD-M such that memory cells of a target word-line designated by the physical address have an erase state and first through 2^{M}−1_th target program states (operation S130).

After a reference time interval elapses from completion of the first program operation, the nonvolatile memory device 400a receives a second program command, the physical address and an N page data PD-N from the storage controller 300 (operation S150).

The nonvolatile memory device 400a performs a second program operation on at least one second memory block selected from the first memory blocks based on the N page data PD-N and degradation information of each of the first memory blocks such that memory cells of the at least one second memory block have an erase state and first through 2^{N}−1_th target program states (operation S170).

The first program operation may correspond to TLC program operation and the second program operation may correspond to QLC program operation.

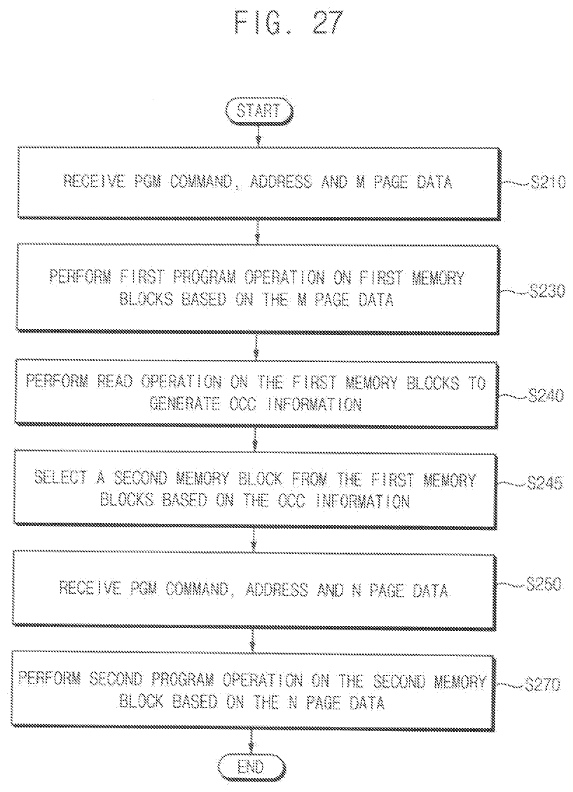

FIG. 27 illustrates a method of operating a storage device according to an embodiment.

Referring to FIGS. 3 through 25 and 27, there is provided a method of operating a storage device 200 including a nonvolatile memory device 400a and a storage controller 300 to control the nonvolatile memory device 400a which includes a memory cell array, where the memory cell array includes a plurality of word-lines stacked on a substrate, a plurality of memory cells provided in a plurality of channel holes extending in a vertical direction with respect to the substrate and a word-line cut region extending in a first horizontal direction and dividing the plurality of word-lines into a plurality of memory blocks.

According to the method, the nonvolatile memory device 400a receives a first program command, a physical address and an M page data M-PD from the storage controller 300 (operation S210).

The nonvolatile memory device 400a performs a first program operation on a first memory block of the memory cell array based on the M page data PD-M, expected retention time information of the M page data PD-M and user request information associated with the M page data PD-M such that memory cells of a target word-line designated by the physical address have an erase state and first through 2^{M}−1_th target program states (operation S230).

The nonvolatile memory device 400a generates ON cell count information by performing a read operation on the first memory blocks in response to a read command from the storage controller 300 (operation S240).

The storage controller 300 selects at least one second memory block on which a second program operation is to be performed based on the ON cell count information (operation S245).

The nonvolatile memory device 400a receives a second program command, the physical address and an N page data PD-N from the storage controller 300 (operation S250).

The nonvolatile memory device 400a performs the second program operation on at least one second memory block such that memory cells of the at least one second memory block have an erase state and first through 2^{N}−1_th target program states based on the N page data PD-N (operation S270).

Therefore, in the storage device and the method of operating the storage device according to an embodiment, the storage controller may selectively perform the first program operation and the second program operation on a plurality of memory blocks of the nonvolatile memory device.

The storage controller may assign a program operation to be performed on the data to be programmed in the plurality of memory blocks to one of a first program operation and a second program operation based on user request information of the data and expected retention time information of the data, may assign M page data to the first program operation, may assign N page data to the second program operation, may assign a logical address of each of the first memory blocks to a first physical address and may assign a logical address of the at least one second memory block to a second physical address.

Therefore, when the first program operation is completed, the memory cells of the first memory blocks have the erase state and first through 2^{M}−1_th target program states instead of intermediate program states, and thus, data may be read from the memory cells of the first memory blocks. In addition, the storage controller may enhance and/or recover charge loss (or, moved threshold voltage distribution) by performing the second program operation on the at least one second memory block for which the probability of degradation of memory cells is greatest from among the first memory blocks.

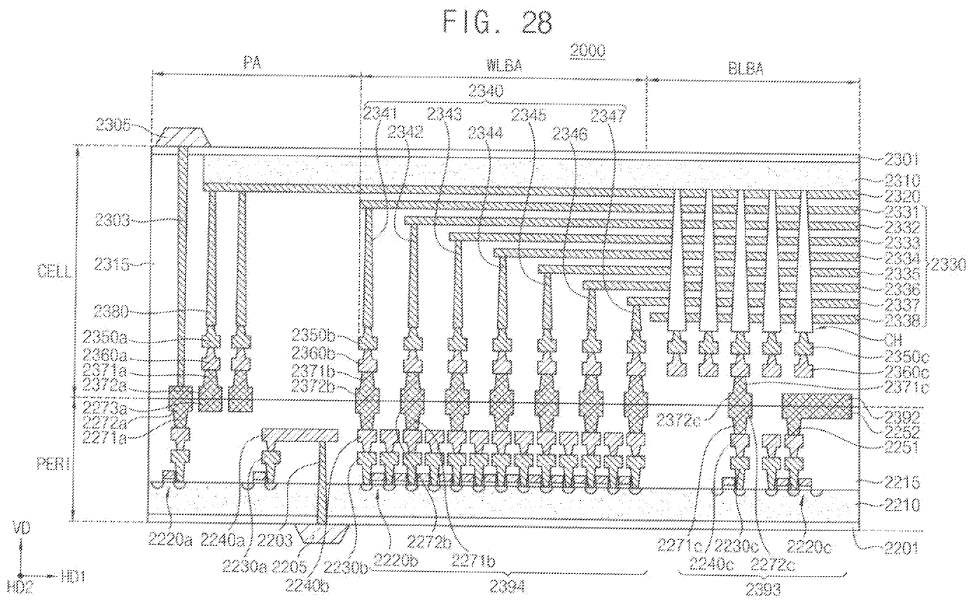

FIG. 28 illustrates a cross-sectional view of a nonvolatile memory device according to an embodiment.

Referring to FIG. 28, a nonvolatile memory device 2000, which may be referred to as a memory device, may have a chip-to-chip (C2C) structure. The C2C structure may refer to a structure formed by manufacturing an upper chip including a memory cell region or a cell region CELL on a first wafer, manufacturing a lower chip including a peripheral circuit region PERI on a second wafer, separate from the first wafer, and then bonding the upper chip and the lower chip to each other. Here, the bonding process may include a method of electrically connecting a bonding metal formed on an uppermost metal layer of the upper chip and a bonding metal formed on an uppermost metal layer of the lower chip. For example, when the bonding metals may include copper (Cu) using a Cu-to-Cu bonding. Embodiments are not necessarily limited thereto. For example, the bonding metals may also be formed of aluminum (Al) or tungsten (W).

Each of the peripheral circuit region PERI and the cell region CELL of the memory device 2000 may include an external pad bonding area PA, a word-line bonding area WLBA, and a bit-line bonding area BLBA.

The peripheral circuit region PERI may include a first substrate 2210, an interlayer insulating layer 2215, a plurality of circuit elements 2220a, 2220b, and 2220c formed on the first substrate 2210, first metal layers 2230a, 2230b, and 2230c respectively connected to the plurality of circuit elements 2220a, 2220b, and 2220c, and second metal layers 2240a, 2240b, and 2240c formed on the first metal layers 2230a, 2230b, and 2230c. In an embodiment, the first metal layers 2230a, 2230b, and 2230c may be formed of tungsten having relatively high electrical resistivity, and the second metal layers 2240a, 2240b, and 2240c may be formed of copper having relatively low electrical resistivity.

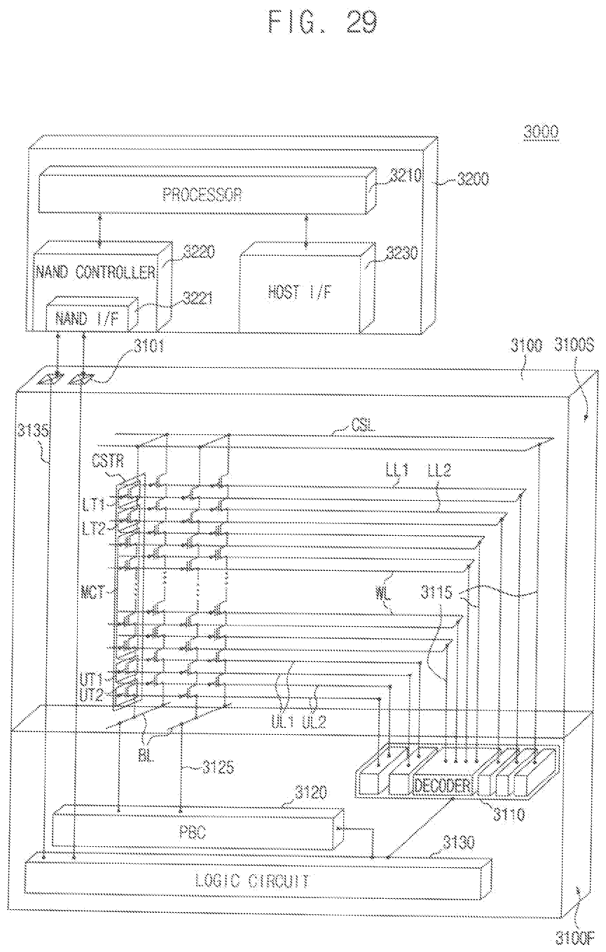

In an embodiment illustrated of FIG. 29, although only the first metal layers 2230a, 2230b, and 2230c and the second metal layers 2240a, 2240b, and 2240c are shown and described, embodiments are not necessarily limited thereto, and one or more additional metal layers may be further formed on the second metal layers 2240a, 2240b, and 2240c. At least a portion of the one or more additional metal layers formed on the second metal layers 2240a, 2240b, and 2240c may be formed of aluminum or the like having a lower electrical resistivity than those of copper forming the second metal layers 2240a, 2240b, and 2240c.

The interlayer insulating layer 2215 may be disposed on the first substrate 2210 and cover the plurality of circuit elements 2220a, 2220b, and 2220c, the first metal layers 2230a, 2230b, and 2230c, and the second metal layers 2240a, 2240b, and 2240c. The interlayer insulating layer 2215 may include an insulating material such as silicon oxide, silicon nitride, or the like.

Lower bonding metals 2271b and 2272b may be formed on the second metal layer 2240b in the word-line bonding area WLBA. In the word-line bonding area WLBA, the lower bonding metals 2271b and 2272b in the peripheral circuit region PERI may be electrically bonded to upper bonding metals 2371b and 2372b of the cell region CELL. The lower bonding metals 2271b and 2272b and the upper bonding metals 2371b and 2372b may be formed of aluminum, copper, tungsten, or the like. Further, the upper bonding metals 2371b and 2372b in the cell region CELL may be referred as first metal pads and the lower bonding metals 2271b and 2272b in the peripheral circuit region PERI may be referred as second metal pads.

The cell region CELL may include at least one memory block. The least one memory block may include a first region and a second region. The first region may store compensation data set and may correspond to SLC block. The cell region CELL may include a second substrate 2310 and a common source line 2320. On the second substrate 2310, a plurality of word-lines 2330, which may include word-line 2331, word-line 2332, word-line 2333, word-line 2334, word-line 2335, word-line 2336, word-line 2337, and word-line 2338 may be stacked in a vertical direction VD (e.g., a Z-axis direction), perpendicular to an upper surface of the second substrate 2310. At least one string selection line and at least one ground selection line may be arranged on and below the plurality of word-lines 2330, respectively, and the plurality of word-lines 2330 may be disposed between the at least one string selection line and the at least one ground selection line.

In the bit-line bonding area BLBA, a channel structure CH may extend in the vertical direction VD, perpendicular to the upper surface of the second substrate 2310, and pass through the plurality of word-lines 2330, the at least one string selection line, and the at least one ground selection line. The channel structure CH may include a data storage layer, a channel layer, a buried insulating layer, and the like, and the channel layer may be electrically connected to a first metal layer and a second metal layer. For example, the first metal layer may be a bit-line contact 2350c, and the second metal layer may be a bit-line 2360c. In an embodiment, the bit-line 2360c may extend in a second horizontal direction HD2 (e.g., a Y-axis direction), parallel to the upper surface of the second substrate 2310.

In an embodiment illustrated of FIG. 28, an area in which the channel structure CH, the bit-line 2360c, and the like are disposed may be defined as the bit-line bonding area BLBA. In the bit-line bonding area BLBA, the bit-line 2360c may be electrically connected to the circuit elements 2220c providing a page buffer circuit 2393 in the peripheral circuit region PERI. The bit-line 2360c may be connected to upper bonding metals 2371c and 2372c in the cell region CELL, and the upper bonding metals 2371c and 2372c may be connected to lower bonding metals 2271c and 2272c connected to the circuit elements 2220c of the page buffer circuit 2393.

In the word-line bonding area WLBA, the plurality of word-lines 2330 may extend in a first horizontal direction HD1 (e.g., an X-axis direction), parallel to the upper surface of the second substrate 2310 and perpendicular to the second horizontal direction HD2, and may be connected to a plurality of cell contact plugs 2340, which may include cell contact plug 2341, cell contact plug 2342, cell contact plug 2343, cell contact plug 2344, cell contact plug 2345, cell contact plug 2346, and cell contact plug 2347. The plurality of word-lines 2330 and the plurality of cell contact plugs 2340 may be connected to each other in pads provided by at least a portion of the plurality of word-lines 2330 extending in different lengths in the first horizontal direction HD1. A first metal layer 2350b and a second metal layer 2360b may be connected to an upper portion of the plurality of cell contact plugs 2340 connected to the plurality of word-lines 2330, sequentially. The plurality of cell contact plugs 2340 may be connected to the peripheral circuit region PERI by the upper bonding metals 2371b and 2372b of the cell region CELL and the lower bonding metals 2271b and 2272b of the peripheral circuit region PERI in the word-line bonding area WLBA.

The plurality of cell contact plugs 2340 may be electrically connected to the circuit elements 2220b forming an address decoder 2394 in the peripheral circuit region PERI. In an embodiment, operating voltages of the circuit elements 2220b forming the address decoder 2394 may be different than operating voltages of the circuit elements 2220c forming the page buffer circuit 2393. For example, operating voltages of the circuit elements 2220c forming the page buffer circuit 2393 may be greater than operating voltages of the circuit elements 2220b forming the address decoder 2394.

A common source line contact plug 2380 may be disposed in the external pad bonding area PA. The common source line contact plug 2380 may be formed of a conductive material such as a metal, a metal compound, polysilicon, or the like, and may be electrically connected to the common source line 2320. A first metal layer 2350a and a second metal layer 2360a may be stacked (e.g., sequentially) on an upper portion of the common source line contact plug 2380. For example, an area in which the common source line contact plug 2380, the first metal layer 2350a, and the second metal layer 2360a are disposed may be defined as the external pad bonding area PA.

Input/output pads 2205 and 2305 may be disposed in the external pad bonding area PA. A lower insulating film 2201 covering a lower surface of the first substrate 2210 may be formed below the first substrate 2210, and a first input/output pad 2205 may be formed on the lower insulating film 2201. The first input/output pad 2205 may be connected to at least one of the plurality of circuit elements 2220a, 2220b, and 2220c disposed in the peripheral circuit region PERI through a first input/output contact plug 2203, and may be separated from the first substrate 2210 by the lower insulating film 2201. In addition, a side insulating film may be disposed between the first input/output contact plug 2203 and the first substrate 2210 to electrically separate the first input/output contact plug 2203 and the first substrate 2210.

An upper insulating film 2301 covering the upper surface of the second substrate 2310 may be formed on the second substrate 2310 and a second input/output pad 2305 may be disposed on the upper insulating film 2301. The second input/output pad 2305 may be connected to at least one of the plurality of circuit elements 2220a, 2220b, and 2220c disposed in the peripheral circuit region PERI through a second input/output contact plug 2303. In this embodiment, the second input/output pad 2305 is electrically connected to a circuit element 2220a.

According to an embodiment, the second substrate 2310 and the common source line 2320 need not be disposed in an area in which the second input/output contact plug 2303 is disposed. In addition, the second input/output pad 2305 need not overlap the word-lines 2330 in the vertical direction HD. The second input/output contact plug 2303 may be separated from the second substrate 2310 in the direction, parallel to the upper surface of the second substrate 2310, and may pass through the interlayer insulating layer 2315 of the cell region CELL to be connected to the second input/output pad 2305.

According to an embodiment, the first input/output pad 2205 and the second input/output pad 2305 may be selectively formed. For example, the memory device 2000 may include only the first input/output pad 2205 disposed on the first substrate 2210 or the second input/output pad 2305 disposed on the second substrate 2310. In an embodiment, the storage device 200 may include both the first input/output pad 2205 and the second input/output pad 2305.

A metal pattern provided on an uppermost metal layer may be provided as a dummy pattern, or the uppermost metal layer may be absent, in each of the external pad bonding area PA and the bit-line bonding area BLBA, respectively included in the cell region CELL and the peripheral circuit region PERI.

In the external pad bonding area PA, the memory device 2000 may include a lower metal pattern 2273a, corresponding to an upper metal pattern 2372a formed in an uppermost metal layer of the cell region CELL, and having the same cross-sectional shape as the upper metal pattern 2372a of the cell region CELL so as to be connected to each other, in an uppermost metal layer of the peripheral circuit region PERI. In the external pad bonding area PA, the memory device 2000 may include lower bonding metals 2271a and 2271b connected to the lower metal pattern 2273a. In the peripheral circuit region PERI, the lower metal pattern 2273a formed in the uppermost metal layer of the peripheral circuit region PERI need not be connected to a contact. Similarly, in the external pad bonding area PA, an upper metal pattern 2372a, corresponding to the lower metal pattern 2273a formed in an uppermost metal layer of the peripheral circuit region PERI, and having the same shape as a lower metal pattern 2273a of the peripheral circuit region PERI, may be formed in an uppermost metal layer of the cell region CELL. Similarly, in the external pad bonding area PA, an upper bonding metal 2371a may be formed and may be electrically connected to the upper metal pattern 2372a.

The lower bonding metals 2271b and 2272b may be formed on the second metal layer 2240b in the word-line bonding area WLBA. In the word-line bonding area WLBA, the lower bonding metals 2271b and 2272b of the peripheral circuit region PERI may be electrically connected to the upper bonding metals 2371b and 2372b of the cell region CELL by a Cu-to-Cu bonding.

Further, in the bit-line bonding area BLBA, an upper metal pattern 2392, corresponding to a lower metal pattern 2252 formed in the uppermost metal layer of the peripheral circuit region PERI, and having the same cross-sectional shape as the lower metal pattern 2252 of the peripheral circuit region PERI, may be formed in an uppermost metal layer of the cell region CELL. A contact need not be formed on the upper metal pattern 2392 formed in the uppermost metal layer of the cell region CELL. The lower metal pattern 2252 may be included in lower bonding metals 2251 and 2252.

In an embodiment, corresponding to a metal pattern formed in an uppermost metal layer in one of the cell region CELL and the peripheral circuit region PERI, a reinforcement metal pattern having the same cross-sectional shape as the metal pattern may be formed in an uppermost metal layer in the other one of the cell region CELL and the peripheral circuit region PERI. A contact need not be formed on the reinforcement metal pattern.

The word-line voltages may be applied to at least one memory block in the cell region CELL through the lower bonding metals 2271b and 2272b in the peripheral circuit region PERI and upper bonding metals 2371b and 2372b of the cell region CELL.

FIG. 29 illustrates an electronic system including a semiconductor device according to an embodiment.

Referring to FIG. 29, an electronic system 3000 may include a semiconductor device 3100 and a controller 3200 electrically connected to the semiconductor device 3100. The electronic system 3000 may be a storage device including one or a plurality of semiconductor devices 3100 or an electronic device including a storage device. For example, the electronic system 3000 may be a solid state drive (SSD) device, a universal serial bus (USB), a computing system, a medical device, or a communication device that may include one or a plurality of semiconductor devices 3100.

The semiconductor device 3100 may be a nonvolatile memory device, for example, a nonvolatile memory device that will be illustrated with reference to FIGS. 5 through 13D. The semiconductor device 3100 may include a first structure 3100F, and a second structure 3100S on the first structure 3100F. The first structure 3100F may be a peripheral circuit structure including a decoder circuit 3110, a page buffer circuit 3120, and a logic circuit 3130. The second structure 3100S may be a memory cell structure including a bit-line BL, a common source line CSL, word-lines WL, first and second upper gate lines UL1 and UL2, first and second lower gate lines LL1 and LL2, and memory cell strings CSTR between the bit line BL and the common source line CSL.

In the second structure 3100S, each of the memory cell strings CSTR may include lower transistors LT1 and LT2 adjacent to the common source line CSL, upper transistors UT1 and UT2 adjacent to the bit-line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be varied in accordance with an embodiment.

In an embodiment, the upper transistors UT1 and UT2 may include string selection transistors, and the lower transistors LT1 and LT2 may include ground selection transistors. The lower gate lines LL1 and LL2 may be gate electrodes of the lower transistors LT1 and LT2, respectively. The word lines WL may be gate electrodes of the memory cell transistors MCT, respectively, and the upper gate lines UL1 and UL2 may be gate electrodes of the upper transistors UT1 and UT2, respectively.

In an embodiment, the lower transistors LT1 and LT2 may include a lower erase control transistor LT1 and a ground selection transistor LT2 that may be connected with each other in serial. The upper transistors UT1 and UT2 may include a string selection transistor UT1 and an upper erase control transistor UT2. At least one of the lower erase control transistor LT1 and the upper erase control transistor UT2 may be used in an erase operation for erasing data stored in the memory cell transistors MCT through gate induced drain leakage (GIDL) phenomenon.

The common source line CSL, the first and second lower gate lines LL1 and LL2, the word lines WL, and the first and second upper gate lines UL1 and UL2 may be electrically connected to the decoder circuit 3110 through first connection wirings 1115 extending to the second structure 3110S in the first structure 3100F. The bit-lines BL may be electrically connected to the page buffer circuit 3120 through second connection wirings 3125 extending to the second structure 3100S in the first structure 3100F.

In the first structure 3100F, the decoder circuit 3110 and the page buffer circuit 3120 may perform a control operation for at least one selected memory cell transistor among the plurality of memory cell transistors MCT. The decoder circuit 3110 and the page buffer circuit 3120 may be controlled by the logic circuit 3130. The semiconductor device 3100 may communicate with the controller 3200 through an input/output pad 3101 electrically connected to the logic circuit 3130. The input/output pad 3101 may be electrically connected to the logic circuit 3130 through an input/output connection wiring 3135 extending to the second structure 3100S in the first structure 3100F.

The controller 3200 may include a processor 3210, a NAND controller 3220, and a host interface 3230. The electronic system 3000 may include a plurality of semiconductor devices 3100, and in this case, the controller 3200 may control the plurality of semiconductor devices 3100.

The processor 3210 may control operations of the electronic system 3000 including the controller 3200. The processor 3210 may be operated by firmware, and may control the NAND controller 3220 to access the semiconductor device 3100. The NAND controller 3220 may include a NAND interface 3221 for communicating with the semiconductor device 3100. Through the NAND interface 3221, control command for controlling the semiconductor device 3100, data to be written in the memory cell transistors MCT of the semiconductor device 3100, data to be read from the memory cell transistors MCT of the semiconductor device 3100, or the like, may be transferred. The host interface 3230 may provide communication between the electronic system 3000 and an outside host. When control command is received from the outside host through the host interface 3230, the processor 3210 may control the semiconductor device 3100 in response to the control command.

A nonvolatile memory device or a storage device according to an embodiment may be packaged using various package types or package configurations.

The present disclosure may be applied to various electronic devices including a storage device. For example, the present disclosure may be applied to systems such as be a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, or the like

The foregoing is illustrative of embodiments and is not intended to be construed as limiting thereof. Although embodiments of the present disclosure have been described by way of example, those of ordinary skill in the pertinent art will readily appreciate that many modifications are possible without materially departing from the scope or spirit of the present disclosure. Accordingly, all such modifications are intended to be included within the scope of the disclosure as defined in the following claims.

What is claimed is:

1. A storage device comprising:
a nonvolatile memory device including a memory cell array, wherein the memory cell array includes a plurality of word-lines stacked on a substrate, a plurality of memory cells provided in a plurality of channel holes extending in a vertical direction with respect to the substrate, and a word-line cut region extending in a first horizontal direction and dividing the plurality of word-lines into a plurality of memory blocks; and
a storage controller configured to control operation of the nonvolatile memory device,
wherein the storage controller is configured to:
assign program operation associated with data to be programmed to one of a first program operation or a second program operation, assign at least one first page of data to the first program operation based on the data and assign at least one second page of data to the second program operation based on the data;
control the nonvolatile memory device to perform the first program operation on first memory blocks from among the plurality of memory blocks such that memory cells of the first memory blocks store the at least one first page of data and to perform the second program operation on at least one second memory block selected from the first memory blocks such that memory cells of the second memory block further store the at least one second page of data; and
control the nonvolatile memory device to select one of the first program operation on a third memory block in an erase state or the second program operation on the second memory block, and to perform the selected program operation after the first program operation on the first memory blocks is completed.

2. The storage device of claim 1, wherein the storage controller is configured to:
assign the program operation to be performed on the data to one of the first program operation and the second program operation based on expected retention time information of the data and user request information on the data;
perform the first program operation on the first memory blocks selected from the plurality of memory blocks based on wear-leveling information of each of the plurality of memory blocks; and
perform the second program operation on the at least one second memory block selected from the first memory blocks based on degradation information of each of the first memory blocks.

3. The storage device of claim 2, wherein the storage controller is configured to:
assign the first program operation in response to an expected retention time of the data being greater than a reference value; and
assign the second program operation in response to the expected retention time of the data being smaller than the reference value.

4. The storage device of claim 2, wherein the user request information includes at least one of a performance of the storage device, a latency associated with the program operation and a reliability of the data, and
wherein the storage controller is, based on the user request information, configured to:
assign the first program operation in response to the user request information being greater than a reference value; and
assign the second program operation in response to the user request information being smaller than the reference value.

5. The storage device of claim 2, wherein the wear-leveling information includes program/erase cycle information of each of the plurality of memory blocks, and
wherein the storage controller is configured to select the first memory blocks from among the plurality of memory blocks such that a program/erase cycle count of each of the plurality of memory blocks is uniform.

6. The storage device of claim 2, wherein the degradation information includes at least one of an ON cell count, an OFF cell count, an error count and elapsed time information from completion of the first program operation of each of the plurality of memory blocks.

7. The storage device of claim 6, wherein the storage controller is configured to:
obtaining the ON cell count by applying a default read voltage to a plurality word-lines of the first memory blocks, the default read voltage discriminating the erase state and a first target program state;
select at least one memory block for which the ON cell count is greater than a reference value, from among the first memory blocks as the second memory block; and
perform the second program operation on the second memory block.

8. The storage device of claim 6, wherein the storage controller is configured to:
obtaining the OFF cell count by applying a default read voltage to a plurality word-lines of the first memory blocks, the default read voltage discriminating a 2^{M}−2_th target program state and a 2^{M}−1_th target program state, M being a natural number;
select at least one memory block for which the OFF cell count is greater than a reference value, from among the first memory blocks as the second memory block; and
perform the second program operation on the second memory block.

9. The storage device of claim 6, wherein the storage controller is configured to:
obtain a read data by applying a read voltage to a plurality word-lines of the first memory blocks after the first program operation is completed; and
obtain the error count by performing an error correction code (ECC) decoding on the read data.

10. The storage device of claim 6, wherein the storage controller is configured to:
select at least one memory block for which the error count is greatest, from among the first memory blocks as the second memory block; and
perform the second program operation on the second memory block.

11. The storage device of claim 6, wherein the storage controller is configured to:
select at least one memory block for which the elapsed time information from completion of the first program operation is greatest, from among the first memory blocks as the second memory block;
perform the second program operation on the second memory block; and
select the second memory block from among the first memory blocks based on a time stamp indicating elapsed time from completion of the first program operation of each of the first memory blocks.

12. The storage device of claim 2, wherein the storage controller is configured to provide a read data to an external host by performing a read operation on at least a portion of the first memory blocks on which the first program operation is completed.

13. The storage device of claim 2, wherein the storage controller is configured to:
perform the first program operation on a portion of a plurality of word-lines of the first memory blocks;
select the at least one second memory block based on the degradation information, from among the first memory blocks on which the first program operation is performed; and
perform the second program operation on rest word-lines of the second memory block.

14. The storage device of claim 2, wherein the storage controller includes:
a program/address assigner; and
a processor configured to control the program/address assigner.
wherein the program/address assigner is configured to:
assign the plurality of memory blocks to first target memory blocks and at least one second target memory block based on the expected retention time information and the user request information, the first program operation to be performed on the first target memory blocks and the second program operation to be performed on the at least one second target memory block;
assign a first logical address of each of the first target memory blocks to a first physical address; and
assign a second logical address of the at least one second target memory block to a second physical address.

15. The storage device of claim 14, further comprising an on-chip memory, and
wherein the on-chip memory is configured to store the degradation information of each of the plurality of memory blocks as a form of a table.

16. The storage device of claim 1, further comprising a buffer memory connected to the storage controller,
wherein the buffer memory is configured to store the at least one first page of data provided from an external host, to be released after the first program operation is completed and to store the at least one second page of data.

17. The storage device 1, wherein the nonvolatile memory device further includes:
a voltage generator configured to generate word-line voltages based on control signals;
an address decoder coupled to the memory cell array through the plurality of word-lines, the address decoder configured to transfer the word-line voltages to the memory cell array based on a row address;
a page buffer circuit coupled to the memory cell array through a plurality of bit-lines, wherein the page buffer circuit is configured to store the at least one first page of data in the memory cell array and is selectively configured to store the at least one second page of data in the memory cell array; and
a control circuit configured to control the page buffer circuit, the address decoder and the voltage generator from a command and an address from the storage controller,
wherein the memory cell array includes the plurality of memory blocks, and
wherein at least one of the plurality of memory blocks includes a plurality of NAND strings, and each of the plurality of NAND strings includes a plurality of memory cells stacked in the vertical direction.

18. A storage device comprising:
a nonvolatile memory device including a memory cell array, wherein the memory cell array includes a plurality of word-lines stacked on a substrate, a plurality of memory cells provided in a plurality of channel holes extending in a vertical direction with respect to the substrate, and a word-line cut region extending in a first horizontal direction and dividing the plurality of word-lines into a plurality of memory blocks; and
a storage controller configured to control operation of the nonvolatile memory device,
wherein the storage controller is configured to:
assign a program operation associated with data to be programmed, to one of a first program operation and a second program operation, assign at least one first page of data to the first program operation based on the data and assign at least one second page of data to the second program operation based on the data;
assign the plurality of memory blocks to first memory blocks and at least one second memory block, the first program operation to be performed on the first memory blocks and the second program operation to be performed on the at least one second memory block;
assign a first logical address of each of the first memory blocks to a first physical address;
assign a second logical address of the at least one second memory block to a second physical address;
control the nonvolatile memory device to perform the first program operation on first memory blocks from among the plurality of memory blocks such that memory cells of the first memory blocks store the at least one first page of data, and to perform the second program operation on at least one second memory block selected from the first memory blocks such that memory cells of the second memory block further store the at least one second page of data; and
control the nonvolatile memory device to select one of the first program operation on a third memory block in an erase state or the second program operation on the second memory block, and to perform the selected program operation after the first program operation on the first memory blocks is completed.

19. The storage device 18, wherein the storage controller is configured to:
assign the program operation to be performed on the data to one of the first program operation and the second program operation based on expected retention time information of the data and user request information on the data; and
perform the second program operation on the at least one second memory block selected from the first memory blocks based on degradation information of each of the first memory blocks.

20. A method of operating a storage device, wherein the storage device includes a nonvolatile memory device and a storage controller configured to control the nonvolatile memory device, and wherein the memory cell array includes a plurality of word-lines stacked on a substrate, a plurality of memory cells provided in a plurality of channel holes extending in a vertical direction with respect to the substrate, and a word-line cut region extending in a first horizontal direction and dividing the plurality of word-lines into a plurality of memory blocks, the method comprising:
receiving, by the nonvolatile memory device, a first program command, a physical address and at least one first page of data from the storage controller;
performing, by the nonvolatile memory device, a first program operation on first memory blocks from among the memory blocks such that memory cells of the first memory blocks store the at least one first page of data;
receiving, by the nonvolatile memory device, a second program command, the physical address and at least one second page of data from the storage controller; and
performing, by the nonvolatile memory device, a second program operation on at least one second memory block selected from the first memory blocks such that memory cells of the at least one second memory block store the at least one second page of data,
wherein one of the first program operation on a third memory block in an erase state or the second program operation on the at least one second memory block, is performed after the first program operation on the first memory blocks is completed.
